(19) United States
(12) Patent Application Publication
(10) Pub. No.: US 2025/0043424 A1
(43) Pub. Date: Feb. 6, 2025

(54) SUBSTRATE PROCESSING APPARATUS, METHOD OF PROCESSING SUBSTRATE, AND METHOD OF MANUFACTURING SEMICONDUCTOR DEVICE

(71) Applicant: KOKUSAI ELECTRIC CORPORATION, Tokyo (JP)

(72) Inventors: Atsushi HIRANO, Toyama-shi (JP); Kenta KASAMATSU, Toyama-shi (JP); Hideyuki NISHIMOTO, Toyama-shi (JP); Taketoshi MORIYA, Toyama-shi (JP)

(73) Assignee: KOKUSAI ELECTRIC CORPORATION, Tokyo (JP)

(21) Appl. No.: 18/920,769

(22) Filed: Oct. 18, 2024

Related U.S. Application Data
(63) Continuation of application No. PCT/JP2022/025622, filed on Jun. 27, 2022.

(51) Int. Cl. C23C 16/455; C23C 16/34; C23C 16/44; H01L 21/02

(52) U.S. Cl. CPC C23C 16/45563; C23C 16/345; C23C 16/4412; H01L 21/0217; H01L 21/02271

(57) ABSTRACT

A substrate processing apparatus includes: (a) a process tube including a cylindrical portion which is closed at an upper end and accommodates at least one substrate therein; (b) a supply buffer provided on a sidewall of the cylindrical portion to protrude outward from the sidewall; (c) at least one first injector provided inward of the supply buffer to extend along an axial direction of an axis of the cylindrical portion; and (d) a plurality of exhausters formed in the sidewall of the cylindrical portion to exhaust a precursor gas, the plurality of exhausters including a pair of exhausters open such that both sides of the pair of exhausters sandwich a virtual plane set to pass through a circumferential center of the cylindrical portion and the axis of the cylindrical portion at a boundary between the supply buffer and the cylindrical portion in a plan view.

### CROSS-REFERENCE TO RELATED APPLICATION

This application is a bypass continuation application of International Application No. PCT/JP2022/025622 having an international filing date of Jun. 27, 2022 and designating the United States, the entire contents of which are incorporated herein by reference.

### TECHNICAL FIELD

The present disclosure relates to a substrate processing apparatus, a substrate processing method, and a method of manufacturing a semiconductor device.

### BACKGROUND

In the related art, a semiconductor manufacturing apparatus for manufacturing a semiconductor device is known as an example of a substrate processing apparatus. As an example of the semiconductor manufacturing apparatus, a vertical-type semiconductor manufacturing apparatus which processes a plurality of substrates while holding them in multiple stages in a vertical direction is disclosed in the related art. In the vertical-type semiconductor manufacturing apparatus, a film-forming process of forming a predetermined film on a surface of the substrate may be performed as substrate processing.

During the film-forming process, when a precursor gas is injected onto the substrate inside a process chamber, a concentration of the precursor gas or an intermediate may deviate due to an uneven flow of the precursor gas on a substrate surface of the substrate. When the concentration of the gas on the substrate surface deviates, an in-plane uniformity of the gas adsorbed on the substrate surface may decrease, or a step coatability (that is, step coverage) may decrease.

### SUMMARY

The present disclosure provides a technique capable of improving uniformity of a flow of a precursor gas on a substrate surface.

According to one embodiment of the present disclosure, there is provided a technique including: (a) a process tube including a cylindrical portion which is closed at an upper end and accommodates at least one substrate therein; (b) a supply buffer provided on a sidewall of the cylindrical portion to protrude outward from the sidewall; (c) at least one first injector provided inward of the supply buffer to extend along an axial direction of an axis of the cylindrical portion; and (d) a plurality of exhausters formed in the sidewall of the cylindrical portion to exhaust a precursor gas, the plurality of exhausters including a pair of exhausters open such that both sides of the pair of exhausters sandwich a virtual plane set to pass through a circumferential center of the cylindrical portion and the axis of the cylindrical portion at a boundary between the supply buffer and the cylindrical portion in a plan view.

According to the present disclosure, it is possible to improve the uniformity of the flow of a precursor gas on a substrate surface.

### BRIEF DESCRIPTION OF DRAWINGS

FIG. 1 is a front view illustrating a substrate processing apparatus according to an embodiment of the present disclosure, which is partially cut away in a vertical plane along a depth direction.

FIG. 2 is a cross-sectional view taken along line 2-2 in FIG. 1, illustrating the substrate processing apparatus according to the embodiment, which is cut away in a horizontal plane.

FIG. 3 is a cross-sectional view taken along line 3-3 in FIG. 2, illustrating a process container of the substrate processing apparatus according to the embodiment of the present disclosure, which is cut away in a vertical plane along a width direction.

FIG. 4 is a side view illustrating a main exhaust slit and a sub-exhaust slit formed in an inner tube of the process container of the substrate processing apparatus according to the embodiment, when viewed from an outer tube.

FIG. 5 is a cross-sectional view illustrating a first injector configured to inject a precursor gas in the substrate processing apparatus according to the embodiment, which is cut away in a horizontal direction.

FIG. 6 is a block diagram illustrating a control system of a controller of the substrate processing apparatus according to the embodiment.

FIG. 7 is a flowchart illustrating a substrate processing process according to the embodiment.

FIG. 8 is a view for explaining a distribution of a concentration of the precursor gas inside a cylindrical portion using a simulation model when a distance between centers of two first injectors of the substrate processing apparatus according to the embodiment is 22 mm.

FIG. 9 is a graph for explaining results of a simulation analyzing a relationship between uniformity of the concentration of the precursor gas and the distance between the centers of the two first injectors.

FIG. 10A is a view illustrating a flow of the precursor gas inside the cylindrical portion and a distribution of a partial pressure when the first injector has one column of injection holes and a pair of sub-exhaust slits is not provided in the substrate processing apparatus according to the embodiment.

FIG. 10B is a view illustrating a flow of the precursor gas inside the cylindrical portion and a distribution of the partial pressure when the first injector has three columns of injection holes and a pair of sub-exhaust slits is not provided in the substrate processing apparatus according to the embodiment.

FIG. 10C is a view illustrating a flow of the precursor gas inside the cylindrical portion and a distribution of the partial pressure when the first injector has three columns of injection holes and a pair of sub-exhaust slits is provided in a substrate processing apparatus according to a seventh modification of the embodiment.

FIG. 11 is a diagram illustrating a state in which a return flow occurs inside the cylindrical portion of the substrate processing apparatus according to this embodiment, with different conditions depending on a shape of the first injector and a flow rate of the precursor gas.

FIG. 12A is a view illustrating a substrate processing apparatus according to a first modification, in which six first injectors are provided.

FIG. 12B is a view illustrating a substrate processing apparatus according to a second modification, in which a plurality of first injectors are arranged to be spaced apart from a substrate.

FIG. 12C is a view illustrating a substrate processing apparatus according to a third modification, in which a sidewall having a slit is provided between each first injector and a substrate and injection holes of a plurality of first injectors are open toward the sidewall on an opposite side to the substrate.

FIG. 12D is a view illustrating a substrate processing apparatus according to a fourth modification, in which a sidewall having a slit is provided between each first injector and a substrate and injection holes of a plurality of first injectors are open toward the sidewall having the slit.

FIG. 12E is a view illustrating a substrate processing apparatus according to a fifth modification, in which a plurality of first injectors are arranged to be spaced apart from a substrate, a sidewall having a slit is provided between each first injector and the substrate, and injection holes of a plurality of first injectors are open toward the sidewall having the slit.

FIG. 13 is a perspective view illustrating a substrate processing apparatus according to a sixth modification, in which fins are provided on each of a main exhaust slit and a sub-exhaust slit.

### DETAILED DESCRIPTION

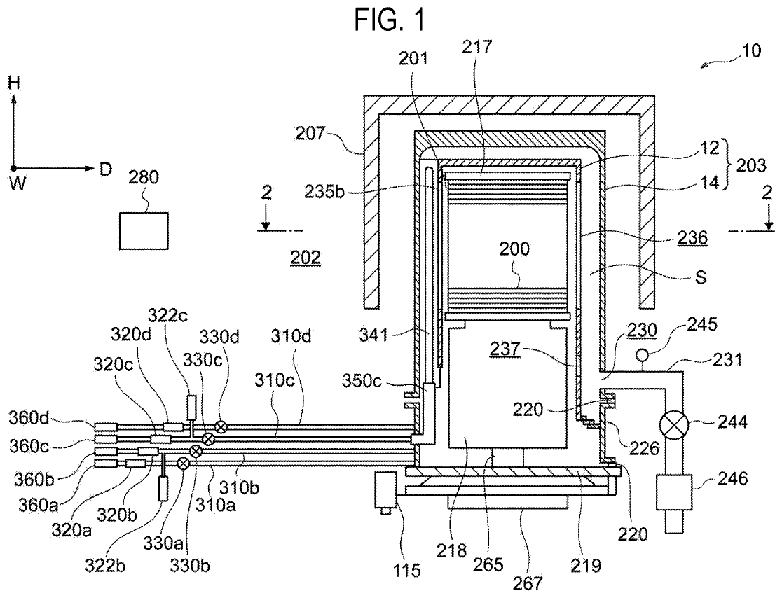

Embodiments of the present disclosure will now be described mainly with reference to FIGS. 1 to 13. The drawings used in the following description are schematic, and relationships between dimensions of respective elements, ratios of the respective elements, and the like used in the drawings may differ from reality. Also, there may be a case where a relationship of dimensions and ratios of respective elements differ from each other between the drawings.

Further, unless otherwise specified in the specification, each element is not limited to one, and a plurality of elements may be provided. Further, throughout the drawings, substantially the same elements will be denoted by the same reference numerals, and duplicated explanations in the specification will be omitted.

### <Overall Configuration of Substrate Processing Apparatus>

First, an overall configuration of a substrate processing apparatus 10 according to the embodiment will be described with reference to FIGS. 1 to 6. An up-down direction H of the apparatus refers to a vertical direction, a width direction W of the apparatus refers to a horizontal direction, and a depth direction D of the apparatus refers to the horizontal direction.

As shown in FIG. 1, the substrate processing apparatus 10 includes a controller 280 which controls each part, and a process furnace 202 The process furnace 202 includes a heater 207 which is a heating means. The heater 207 has a cylindrical shape and is provided vertically by being supported on a heater base (not shown). The heater 207 also functions as an activation mechanism for activating a process gas with heat. Details of the controller 280 will be described later.

A reaction tube 203 as a process tube provided concentrically with the heater 207 and constituting a reaction container is arranged upright inside the heater 207. The reaction tube 203 corresponds to a process container of the present disclosure. The reaction tube 203 is made of a heat resistant material such as quartz (SiO₂) or silicon carbide (SiC). The substrate processing apparatus 10 is of a so-called hot-wall type.

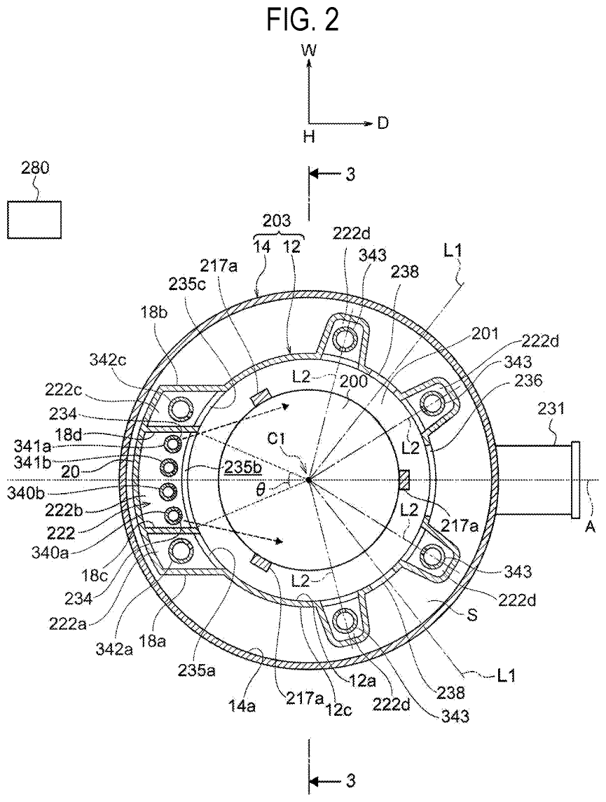

As shown in FIG. 2, the reaction tube 203 has a cylindrical inner tube 12 and a cylindrical outer tube 14 provided so as to surround the inner tube 12. That is, the outer tube 14 and the inner tube 12 constitute the reaction tube 203. The outer tube 14 surrounds the inner tube 12 to form a gap serving as an exhaust space S between a cylindrical portion of the inner tube 12 and the outer tube 14. The inner tube 12 is arranged concentrically with the outer tube 14. The inner tube 12 is an example of a tube member.

The inner tube 12 has a closed upper portion, and a sidewall as a cylindrical portion in which a plurality of substrates is accommodated. Specifically, as shown in FIG. 1, the inner tube 12 is formed in a shape with a ceiling, with its lower end opened and its upper end closed with a flat wall. The outer tube 14 is also formed in a shape with a ceiling, with its lower end opened and its upper end closed with a flat wall.

Further, as shown in FIG. 2, a supply buffer 222 is formed as a nozzle chamber in the exhaust space S formed between the inner tube 12 and the outer tube 14. That is, the supply buffer 222 is a supply space in which a nozzle for supplying a process gas is arranged. Details of the supply buffer 222 will be described later.

As shown in FIG. 1, a process chamber 201 for processing wafers 200 as substrates is formed inside the inner tube 12. Further, the process chamber 201 may accommodate a boat 217, which is an example of a substrate holder capable of holding the wafers 200 in a horizontal posture and aligned vertically in multiple stages. The inner tube 12 surrounds the wafers 200 accommodated therein. The plurality of wafers 200 are arranged inside the cylindrical portion of the inner tube 12 along an axial direction of the cylindrical portion. Details of the inner tube 12 will be described later.

A lower end of the reaction tube 203 is supported by a cylindrical manifold 226. The manifold 226 is made of metal such as a nickel alloy or stainless steel, or a heat resistant material such as SiO₂ or SiC. A flange is formed at an upper end portion of the manifold 226. A lower end portion of the outer tube 14 is provided on the flange. A sealing member 220 such as an O-ring is disposed between the flange and the lower end portion of the outer tube 14, making the interior of the reaction tube 203 airtight.

A seal cap 219 is air-tightly attached to an opening at the lower end of the manifold 226 via the sealing member 220 such as an O-ring, so that the opening at the lower end of the reaction tube 203, that is, the opening of the manifold 226, is air-tightly closed. The seal cap 219 is made of metal such as a nickel alloy or stainless steel, and is formed in a disc shape. The seal cap 219 may be configured to cover its outside with a heat resistant material such as SiO₂ or SiC.

A boat support stand 218 for supporting the boat 217 is provided on the seal cap 219. The boat support stand 218 is made of a heat resistant material such as SiO₂ or SiC and functions as a heat insulator.

The boat 217 is provided upright on the boat support stand 218. The boat 217 is made of a heat resistant material such as SiO₂ or SiC. As shown in FIG. 2, the boat 217 includes a bottom plate (not shown) fixed to the boat support stand 218 and a ceiling plate arranged above the bottom plate. A plurality of posts 217a are provided between the bottom plate and the ceiling plate.

A plurality of wafers 200 to be processed in the process chamber 201 in the inner tube 12 are held in the boat 217. As shown in FIG. 2, the plurality of wafers 200 are supported by the posts 217a of the boat 217 while being maintained in a horizontal posture at a certain interval and with their centers aligned. A loading direction of the plurality of wafers 200 corresponds to an axial direction of the reaction tube 203. That is, the centers of the substrates are aligned with the central axis of the boat 217. Thus, the central axis of the boat 217 coincides with the central axis of the reaction tube 203.

A rotation mechanism 267 for rotating the boat is provided below the seal cap 219. A rotary shaft 265 of the rotation mechanism 267 penetrates the seal cap 219 and is connected to the boat support stand 218. The wafers 200 are rotated by rotating the boat 217 via the boat support stand 218 using the rotation mechanism 267.

The seal cap 219 is raised and lowered vertically by an elevator 115 as a lifting mechanism provided outside the reaction tube 203, so that the boat 217 may be loaded into and unloaded from the process chamber 201.

A plurality of nozzle supports which supports a gas nozzle 342a for supplying a gas to the interior of the process chamber 201, a return nozzle 340, a return nozzle 341, and a gas nozzle 342c are provided in the manifold 226 so as to penetrate the manifold 226. In this embodiment, four nozzle supports are provided. The return nozzle 341 and the nozzle support 350c are illustrated in FIG. 1. The nozzle supports are made of a material such as a nickel alloy or stainless steel.

Gas supply pipes 310a to 310d for supplying a gas to the interior of the process chamber 201 are connected to one ends of the nozzle supports, respectively. Further, the gas nozzle 342a, the return nozzle 340, the return nozzle 341, and the gas nozzle 342c are connected to the other ends of the nozzle supports, respectively. The gas nozzles 342a and 342c are made of a heat resistant material such as SiO₂ or SiC. Details of the gas nozzles 342a and 342c will be described later.

### (Gas Supply Pipe)

The gas supply pipe 310a is in communication with the corresponding gas nozzle 342a via a nozzle support (not shown). The gas supply pipe 310d is in communication with the corresponding gas nozzle 342c via a nozzle support (not shown). The gas supply pipe 310b is in communication with the return nozzle 340 via a nozzle support (not shown). The gas supply pipe 310c is in communication with the return nozzle 341 via the nozzle support 350c (not shown).

The gas supply pipe 310a is provided with a gas source 360a for supplying an assist gas as a process gas, a mass flow controller (MFC) 320a as an example of a flow rate controller, and a valve 330a as an opening/closing valve, in this order from the upstream side in a gas flow direction. The gas supply pipe 310b is provided with a gas source 360b for supplying a precursor gas as a process gas, an MFC 320b, a tank 322b, and a valve 330b in this order from the upstream direction.

The gas supply pipe 310c is provided with a gas source 360c for supplying a precursor gas as a process gas, an MFC 320c, a tank 322c, and a valve 330c in this order from the upstream direction. The gas supply pipe 310d is provided with a gas source 360d for supplying a reaction gas as a process gas, an MFC 320d, and a valve 330d in this order from the upstream direction.

The reaction gas is supplied from the gas supply pipe 310d. The precursor gas is supplied from the gas supply pipes 310b and 310c. Although not shown, each gas nozzle in this embodiment is provided with a gas supply pipe for supplying a nitrogen (N₂) gas or the like as a purge or assist gas, together with an MFC and a valve.

A plurality of exhaust slits including a main exhaust slit 236 and a sub-exhaust slit 238 are formed in the sidewall of the inner tube 12. The plurality of exhaust slits exhaust a gas in the inner tube 12 to the exhaust space S therethrough. The main exhaust slit 236 in this embodiment corresponds to an exhauster in the present disclosure, which is a main exhauster. The sub-exhaust slit 238 in this embodiment corresponds to an exhauster in the present disclosure, which is a sub-exhauster. In this embodiment, the number of exhaust slits is three, consisting of one main exhaust slit 236 and two sub-exhaust slits 238. In the present disclosure, the number of exhaust slits may be at least two or more.

A lower exhaust port 237 is an auxiliary opening provided in the inner tube below the main exhaust slit 236 and exhausts a gas in the vicinity of the boat support stand 218 therethrough. The lower exhaust port 237 is not essential.

The outer tube 14 of the reaction tube 203 is formed with an exhaust port 230 as an exhaust port. The exhaust port 230 is formed below the lower end of the main exhaust slit 236 and communicates the exhaust space S with the outside of the reaction tube 203. As shown in FIG. 2, the exhaust port 230 is arranged on the opposite side of the supply buffer 222. In a plan view, the supply buffer 222, the exhaust port 230, and the main exhaust slit 236 (to be described later) are arranged to be aligned on a straight line passing through the centers of the substrates.

The exhauster may be, for example, an exhaust port which has an opening communicating the interior of the process chamber 201 with the exhaust space S and indirectly exhausts a gas in the process chamber 201 to the outside via the exhaust space S, or may be an opening directly connected to an exhaust duct to be described later. The latter will be described later as a seventh modification. The exhaust duct 231 is a conduit extending outward from the exhaust port 230 and guides the exhaust of the gas from the reaction tube 203 to a vacuum pump 246 as a vacuum exhauster.

The exhaust duct 231 is provided with a pressure sensor 245 configured to detect an internal pressure of the process chamber 201, and an APC (Auto Pressure Controller) valve 244 as a pressure regulator. A waste gas treater (not shown) and the like are connected to a downstream side of the vacuum pump 246. Thus, by controlling the output of the vacuum pump 246 and the opening of the APC valve 244, the process chamber 201 may be vacuum-exhausted to a predetermined pressure (vacuum degree).

Further, a temperature sensor (not shown) as a temperature detector is provided inside the reaction tube 203 or on the outer wall of the reaction tube 203. Power supplied to the heater 207 is adjusted based on information about the temperature detected by the temperature sensor so that an internal temperature of the process chamber 201 has a desired temperature distribution.

In this specification, a processing temperature means a temperature of the wafer 200 or an internal temperature of the process chamber 201, and a processing pressure means an internal pressure of the process chamber 201. Further, a processing time means a time for which the processing is continued. This holds true in the following descriptions.

In the process furnace 202, the boat 217 configured to transfer the plurality of wafers 200 to be batch-processed in multiple stages is loaded into the process chamber 201 by the boat support stand 218. Then, the wafers 200 loaded into the process chamber 201 are heated to a predetermined temperature by the heater 207. An apparatus having the process furnace is called a vertical batch apparatus.

### <Configurations of Main Parts>

Next, the supply buffer 222, the return nozzles 340 and 341 as a first injector, and the exhaust slits including the main exhaust slit 236 and the sub-exhaust slit 238 in the substrate processing apparatus 10 according to this embodiment will be described in detail. The first injector is not limited to a tubular member such as a nozzle, as long as it is possible to inject the precursor gas into the process chamber 201.

### (Supply Buffer)

As shown in FIG. 2, the supply buffer 222 is provided on the sidewall of the cylindrical portion of the inner tube 12 and is a region that protrudes outward from the sidewall. The supply buffer 222 is formed in the exhaust space S between an outer peripheral surface 12c of the inner tube 12 and an inner peripheral surface 14a of the outer tube 14. The supply buffer 222 is divided into three portions along a circumferential direction of the cylindrical portion by a third partition 18c and a fourth partition 18d.

The supply buffer 222 is formed between a first partition 18a and a second partition 18b and between the inner tube 12 and an arc-shaped ceiling plate 20 which connects a leading end of the first partition 18a and a leading end of the second partition 18b. Both the first partition 18a and the second partition 18b extend from the outer peripheral surface 12c of the inner tube 12 toward the outer tube 14. Both the first partition 18a and the second partition 18b are continuous with the inner tube 12.

The third partition 18c and the fourth partition 18d, which extend from the outer peripheral surface 12c of the inner tube 12 toward the ceiling plate 20, are formed inside the supply buffer 222. Both the third partition 18c and the fourth partition 18d extend toward the ceiling plate 20 in parallel with the first partition 18a and the second partition 18b. The third partition 18c and the fourth partition 18d are arranged in this order from the first partition 18a toward the second partition 18b.

The ceiling plate 20 is separated from the outer tube 14. A leading end of the third partition 18c on the opposite side to the wafer 200 and a leading end of the fourth partition 18d on the opposite side to the wafer 200 are brought into contact with the ceiling plate 20. The first partition 18a, the second partition 18b, the third partition 18c, the fourth partition 18d, and the ceiling plate 20 are examples of a partition member.

The first partition 18a and the second partition 18b form a central portion 222b of the divided portions of the supply buffer 222. The return nozzles 340 and 341 for supplying the precursor gas are provided in the central portion 222b.

At a boundary location between the central portion 222b of the supply buffer 222 and the cylindrical portion, a fan shape is formed by a virtual arc connecting both ends of the cylindrical portion in the circumferential direction and the center C1 of the wafer 200. In this embodiment, a central angle θ of the fan shape is less than 30 degrees. When the central angle θ is 30 degrees or more, a circumferential width of the cylindrical portion of the supply buffer 222 becomes wider so that more gas nozzles may be provided in the supply buffer 222, which increases a manufacturing cost and downtime of the apparatus even if an inexpensive tubular nozzle is used.

Further, the central angle θ of the fan shape may be more preferably 15 degrees or more and 45 degrees or less. When the central angle θ of the fan shape is less than 15 degrees, it becomes difficult to uniformly expose the entire surface of the wafer to the precursor gas. Further, when the central angle θ of the fan shape exceeds 45 degrees, the superiority of this example in which the plurality of nozzles are arranged is lost for the above reasons. In the present disclosure, the central angle of the fan shape may be set arbitrarily.

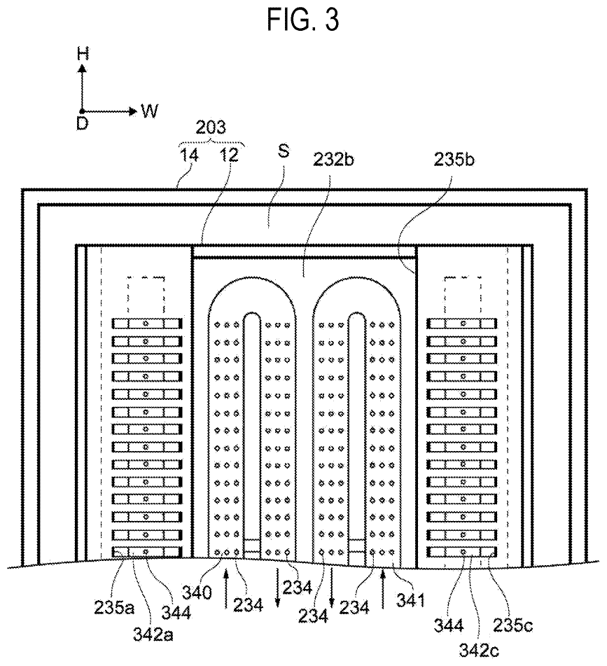

As shown in FIG. 2, a supply slit 235b is formed in the central portion 222b of the supply buffer 222 on the inner peripheral surface 12a on the side of the supply slits 235a and 235c of the inner tube 12. As shown in FIG. 3, the supply slit 235b opens over the entire vertical direction H of the apparatus and the entire width direction W of the apparatus in the central portion 222b. Therefore, the entire return nozzles 340 and 341 in the vertical direction H of the apparatus and the width direction W of the apparatus face the wafer 200 inside the cylindrical portion.

### (First Injector)

The return nozzles 340 and 341, which are the plurality of gas nozzles, are provided inside the supply buffer 222 and extend along the axial direction of the cylindrical portion. Specifically, four nozzles including two gas nozzles 340a and 340b and two gas nozzles 341a and 341b are configured to be arranged along the circumferential direction of the cylindrical portion so as to be capable of supplying the same precursor gas. The four gas nozzles 340a, 340b, 341a, and 341b in this embodiment correspond to a plurality of gas nozzles in the present disclosure.

### (Return Nozzle)

In this embodiment, the four gas nozzles 340a, 340b, 341a, and 341b are formed by two return nozzles 340 and 341. That is, the gas nozzles 340a and 340b adjacent to each other on the lower side of the width direction W in FIG. 2 are formed by one return nozzle 340, and the gas nozzles 341a and 341b adjacent to each other on the upper side opposite the gas nozzles 340a and 340b in the width direction W are formed by another return nozzle 341. In the present disclosure, two nozzles may be formed by only one return nozzle.

Further, in the present disclosure, the number of return nozzles 340 and 341 may be one, or may be any number of two or more. In addition, in the present disclosure, the plurality of nozzles do not necessarily have to be return nozzles, and may be, for example, an arrangement (nozzle array) of the plurality of nozzles independent of each other.

As shown in FIG. 3, the return nozzle 340 has an outward pipe corresponding to the gas nozzle 340a and a return pipe corresponding to the gas nozzle 340b. An upper end of the outward pipe and an upper end of the return pipe are in communication with each other, so that the precursor gas flows through each of them. The return nozzle 341 is configured to be in a plane symmetry with the return nozzle 340. The return pipes of the return nozzles 340 and 341 are adjacent to each other and are arranged to be spaced apart from each other. In this embodiment, an inner diameter of the outward pipe and an inner diameter of the return pipe may be identical to each other. In the present disclosure, the inner diameter of the outward pipe and the inner diameter of the return pipe may be different from each other.

### (Injection Hole)

Each of the outward and return pipes of the return nozzles 340 and 341 has three or more columns of injection holes 234 extending along a longitudinal direction of the return nozzle. The injection holes 234 provide a cylindrical flow path through which the interior and exterior of the return nozzle are in communication with each other. Such injection holes usually form a subsonic jet, but a velocity boundary layer formed may act like a Laval nozzle to implement a supersonic flow. The same precursor gas is injected from the injection holes 234. The precursor gas is injected radially in a plan view.

In addition, in the present disclosure, each of the gas nozzles 340a, 340b, 341a, and 341b has been described to include three or more columns of injection holes arranged along the vertical direction, but this is not essential. For example, each of the gas nozzles 340a, 340b, 341a, and 341b may include three or more injection holes arranged along the circumferential direction of the cylindrical portion in a plane parallel to the surface of the substrate. In addition, in the present disclosure, the number of injection holes may be arbitrarily set to one, two, or four or more.

Among the four gas nozzles 340a, 340b, 341a, and 341b arranged side by side in the central portion 222b of the supply buffer 222, the gas nozzle 340a and the gas nozzle 341a on both sides in the width direction W inject the precursor gas toward the outermost side of the wafer 200. In addition, the injection hole 234 on the most opposite side in the width direction W to the gas nozzle 341a among the three injection holes 234 of the gas nozzle 340a on the lowest stage in FIG. 2, which is on the most opposite side in the width direction W to the gas nozzle 341a, and the injection hole 234 on the most opposite side in the width direction W to the gas nozzle 340a among the three injection holes 234 of the gas nozzle 341a on the highest stage in FIG. 2, which is on the most opposite side in the width direction W to the gas nozzle 340a, inject the precursor gas toward the outermost side of the wafer 200.

In FIG. 2, the injection direction of each injection hole 234 which injects the precursor gas toward the outermost side of the wafer 200 in a plan view is illustrated by a dotted arrow. A space through which the precursor gas may move linearly along the injection direction is formed between the wafer 200 and each injection hole 234 which injects the precursor gas toward the outermost side of the wafer 200. That is, no other structure such as a partition wall is provided between the injection holes 234 and the wafer 200 in the injection direction. In the present disclosure, other structures may be arranged between the wafer and at least one injection hole 234 which injects the precursor gas toward the outermost side of the wafer.

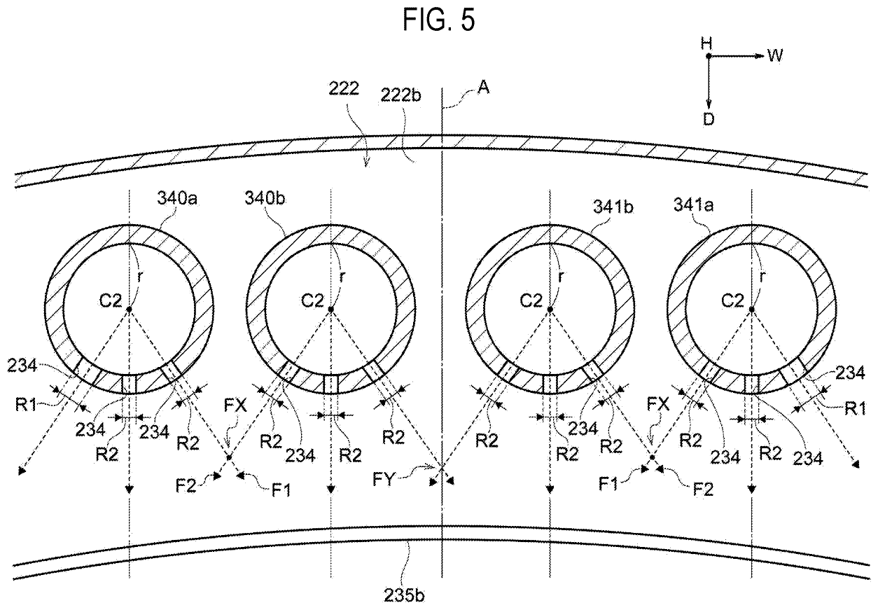

As shown in FIG. 5, in this embodiment, a diameter R1 of the injection hole 234 through which the precursor gas is injected toward the outermost side from the center C1 of the wafer 200 in a plan view (that is, both ends of the width direction W of the apparatus in FIG. 5) is larger than a diameter R2 of the other injection holes 234. In the present disclosure, among the injection holes 234, the diameter of the injection hole 234 through which the precursor gas is injected toward the outermost side from the center C1 of the wafer 200 may be equal to or smaller than the diameter of the other injection holes 234.

As shown in FIG. 5, in this embodiment, a first injection direction F1, which is the closest to the return pipe, among the injection directions of the injection holes 234 of the outward pipe of one return nozzle, and a second injection direction F2, which is the closest to the outward pipe, among the injection directions of the injection holes 234 of the return pipe, intersect with each other in the central portion 222b of the supply buffer 222 away from the wafer 200.

For example, the gas nozzle 340a of the return nozzle 340 on the left side of a virtual plane A in FIG. 5 is the outward pipe, and the gas nozzle 340b on the right side is the return pipe. Among the three injection holes 234 of the gas nozzle 340a of the outward pipe, the injection direction F1 of the rightmost injection hole 234 is closest to the gas nozzle 340b of the adjacent return pipe. In addition, among the three injection holes 234 of the gas nozzle 340b of the return pipe, the injection direction F2 of the leftmost injection hole 234 is closest to the gas nozzle 340a of the adjacent outward pipe.

The injection direction F1 of the rightmost injection hole 234 of the gas nozzle 340a of the outward pipe and the injection direction F2 of the leftmost injection hole 234 of the gas nozzle 340b of the return pipe intersect each other at an intersection FX. In FIG. 5, the intersection FX is illustrated as being inward of the central portion 222b of the supply buffer 222. Similarly, in the two gas nozzles 341a and 341b of the return nozzle 341 on the right side of the virtual plane A in FIG. 5, the intersection FX of the first injection direction F1 and the second injection direction F2 is illustrated as being inward of the central portion 222b of the supply buffer 222.

In addition, in this embodiment, the inner diameter of the outward pipe and the inner diameter of the return pipe have a same radius r. The first injection direction F1 and the second injection direction F2 intersect each other outside the wafer 200, that is, at a position away from the wafer 200, within a distance of 3r from the center C2 of the outward pipe and within a distance of 3r from the center C2 of the return pipe in a plan view. In addition, an intersection FY of the respective injection directions may be similarly defined between the gas nozzle 340b of the return nozzle 340 and the gas nozzle 341b of the return nozzle 341 which are adjacent to each other. Like the intersection FX, the intersection FY is located away from the wafer 200 within a distance of 3r from the center C2 of the outward pipe and within a distance of 3r from the center C2 of the return pipe. Further, when a distance between the center C2 and the intersection FX and a distance between the center C2 and the intersection FY are made to match, gases may be mixed more uniformly.

In the present disclosure, a position of the intersection of the first injection direction with the second injection direction is not limited to the position of the intersection in this embodiment. In addition, only the state in which the first injection direction F1 and the second injection direction F2 intersect each other within the supply buffer 222 away from the wafer 200 may be implemented. In addition, when the inner diameter of the outward pipe and the inner diameter of the return pipe have the same radius r, only the state in which the first injection direction F1 and the second injection direction F2 intersect each other at a position away from the wafer 200 within the distance of 3r from the center C2 of the outward pipe and within the distance of 3r from the center C2 of the return pipe in a plan view may be implemented.

### <Exhaust Slit>

As shown in FIG. 2, the plurality of exhaust slits including the main exhaust slit 236 and the sub-exhaust slit 238 are formed in the sidewall of the cylindrical portion and exhaust the precursor gas from the interior of the cylindrical portion therethrough. In the present disclosure, the main exhaust slit 236 is not essential.

### (Main Exhaust Slit)

The main exhaust slit 236 is formed on the sidewall of the cylindrical portion on the opposite side to the supply buffer 222 with respect to the center C1 of the wafer 200. The main exhaust slit 236 opens on the side of each wafer 200 and exhausts the precursor gas and the like flowing over the wafer 200 therethrough. The main exhaust slit 236 may be formed as a single opening extending between the side of the uppermost wafer 200 and the side of the lowermost wafer 200, or as a plurality of holes distributed between them.

### (Sub-Exhaust Slit)

The two sub-exhaust slits 238 open with the virtual plane A, which is set on the interior of the cylindrical portion, sandwiched from both sides. As shown in FIG. 2, the virtual plane A is set to pass through the circumferential center of the cylindrical portion at the boundary between the supply buffer 222 and the cylindrical portion and the axis of the cylindrical portion in a plan view. The axis of the cylindrical portion overlaps the center of the wafer 200.

As a pair of exhaust slits, the two sub-exhaust slits 238 sandwich the main exhaust slit 236 in the same height range as the main exhaust slit 236. In a plan view, a first virtual line L1 connecting the center of the sub-exhaust slit 238 and the center C1 of the wafer 200 is set. In this embodiment, an angle between the first virtual line L1 and the virtual plane A is an obtuse angle. In the present disclosure, the angle between the first virtual line L1 and the virtual plane A is not limited to the obtuse angle.

As shown in FIG. 2, the width of each of the two sub-exhaust slits 238 in the circumferential direction of the cylindrical portion is smaller than the width of the main exhaust slit 236 at the same height. In the present disclosure, the width of the sub-exhaust slit 238 may be equal to or larger than the width of the main exhaust slit 236.

As shown in FIG. 2, the return nozzles 340 and 341 and the two sub-exhaust slits 238 are configured in symmetry to the virtual plane A. In the present disclosure, it is not essential that the return nozzles 340 and 341 and the pair of exhaust slits are configured in symmetry to the virtual plane A.

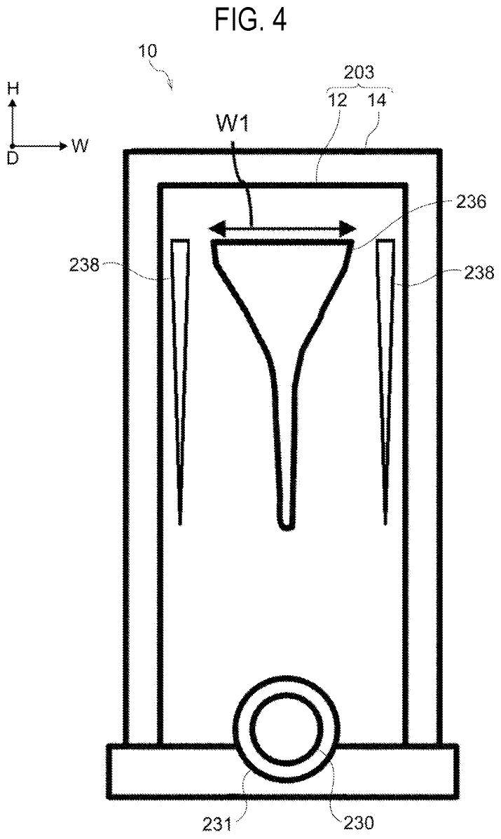

As shown in FIG. 4, in this embodiment, an opening width W1 of the main exhaust slit 236 along the circumferential direction of the cylindrical portion narrows from the side opposite the exhaust port 230 (that is, the upper side in FIG. 4) toward the exhaust port 230 (that is, the lower side in FIG. 4) along the axial direction of the cylindrical portion. Similarly, the opening width of each of the pair of sub-exhaust slits 238 along the circumferential direction of the cylindrical portion narrows from the side opposite a sub-exhaust port (that is, the upper side in FIG. 4) toward the sub-exhaust port (that is, the lower side in FIG. 4) along the axial direction of the cylindrical portion. The sub-exhaust port is not illustrated.

In the present disclosure, the opening width of each of the main exhaust slit 236 and the pair of sub-exhaust slits 238 along the circumferential direction of the cylindrical portion may be set arbitrarily. In FIG. 4, for the sake of easier understanding of the drawings, a counter buffer is not illustrated. The counter buffer will be described later.

### (Tank)

As shown in FIG. 1, the substrate processing apparatus 10 according to this embodiment further includes the tanks 322b and 322c connected to the return nozzles 340 and 341. The tanks 322b and 322c may store the precursor gas alone so that the precursor gas is not mixed with a carrier gas. The tanks 322b and 322c supply the stored precursor gas to the return nozzles 340 and 341 almost simultaneously in a pulse-like manner via an opening/closing valve.

That is, in this embodiment, a flush supply of a high-concentration precursor gas may be performed. In the flush supply, the precursor gas stored in the tanks 322b and 322c is supplied at a large flow rate from the tanks 322b and 322c toward the reaction tube 203. The precursor gas supplied at the large flow rate is also called a “flush flow.” The precursor gas of the flush flow flows at a relatively high speed on the surface of the wafer 200 inside the cylindrical portion of the inner tube 12 during the film-forming process.

In the flush supply, the entire surface of the wafer 200 is exposed to a high-speed flow of the precursor gas during the film-forming process. A high-speed gas flow is one of the most effective means for promoting replacement of gas inside fine structures such as trenches and holes formed in the surface of the wafer 200, and is particularly useful in processing patterned wafers with high aspect ratios.

The present disclosure is not limited to the flush supply of the precursor gas, and may be applied to, for example, a large-flow-rate supply which supplies ammonia (NH₃) as a purge gas at a large flow rate using a typical MFC. Therefore, in the present disclosure, the tanks 322b and 322c for the flush supply are not essential.

In this embodiment, a total instantaneous maximum flow rate of the precursor gas injected in a pulse-like manner from each of the return nozzles 340 and 341 is 1 slm or more and 300 slm or less. When the total instantaneous maximum flow rate of the precursor gas is less than 1 slm, flow velocity may be insufficient, resulting in a change in quality of the precursor gas while flowing over the wafer 200. Further, the replacement of gas inside the fine structures may be insufficient, resulting in a decrease in the quality and uniformity of the film. When the total instantaneous maximum flow rate of the precursor gas exceeds 300 slm, the replacement promotion effect is saturated while the flow rate of the precursor gas becomes too large, resulting in an increase in the cost of the precursor gas.

Further, the total instantaneous maximum flow rate of the precursor gas may be more preferably 12 slm or more and 50 slm or less. When the total instantaneous maximum flow rate of the precursor gas is less than 12 slm, the flow velocity on the wafer 200 may not be sufficiently high (for example, 10 m/s or more), resulting in insufficient step coverage of a formed film. When the total instantaneous maximum flow rate of the precursor gas exceeds 50 slm, a configuration of a supply system for storing the precursor gas in a tank at a high pressure without decomposing the precursor gas becomes complicated, resulting in an increase in the cost of the apparatus. In the present disclosure, the total instantaneous maximum flow rate of the precursor gas injected in a pulse-like manner is not limited to the above, and may be changed as appropriate.

### (Second Injector)

As shown in FIG. 2, the substrate processing apparatus 10 according to this embodiment further includes the gas nozzles 342a and 342c as a second injector for supplying an assist gas. The gas nozzles 342a and 342c are provided in portions 222a and 222c on both sides of the supply buffer 222, respectively. In the present disclosure, the second injector is not essential. The second injector is not limited to a tubular member such as a nozzle, as long as it is capable of injecting the precursor gas.

As shown in FIG. 2, a partition wall is provided between the portions 222a and 222c on both sides of the supply buffer 222 in the width direction W and the cylindrical portion. In addition, as shown in FIG. 3, the supply slits 235a and 235c are formed in the partition wall. The gas nozzles 342a and 342c have a plurality of injection holes 344 along the vertical direction.

### (Third Injector)

As shown in FIG. 2, the substrate processing apparatus 10 according to this embodiment further includes a counter nozzle 343 as a third injector for supplying an assist gas. One or more counter nozzles 343 may be provided at a position in which an angle between a second virtual line L2 connecting the injection direction of the counter nozzle 343 and the center C1 of the wafer 200 and the virtual plane A is an obtuse angle in a plan view.

The counter nozzle 343 is accommodated in a counter buffer 222d. The counter buffer 222d is a region provided on the sidewall of the cylindrical portion of the inner tube 12 and protrudes outward from the sidewall, similar to the supply buffer 222. The counter buffer 222d may be provided between the main exhaust slit 236 and the two sub-exhaust slits 238 in the circumferential direction of the cylindrical portion or between the supply buffer 222 and the two sub-exhaust slits 238. In the present disclosure, the counter nozzle 343 is not essential. A temperature sensor may be arranged in the counter buffer 222d. The third injector is not limited to a tubular member such as a nozzle, as long as it is capable of injecting the process gas.

### (Controller)

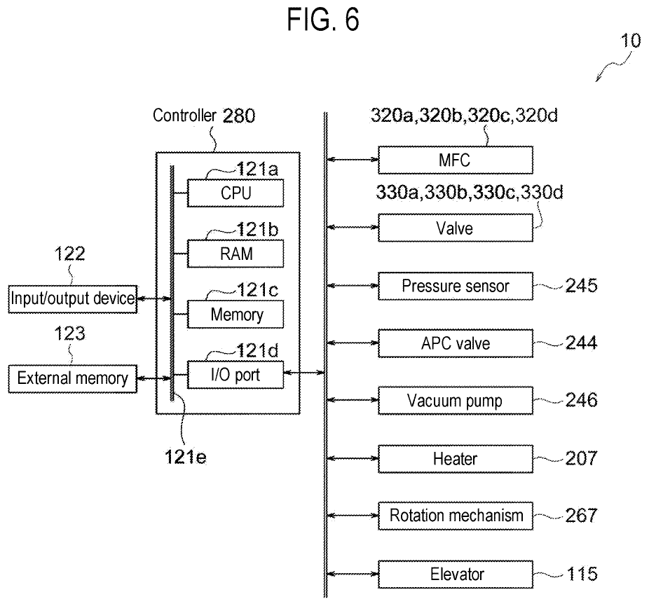

Next, the controller 280 will be described with reference to FIG. 6. FIG. 6 is a block diagram illustrating the substrate processing apparatus 10. The controller 280 (that is, a controller) of the substrate processing apparatus 10 is configured as a computer. The computer includes a CPU (Central Processing Unit) 121a, a RAM (Random Access Memory) 121b, a memory 121c, and an I/O port 121d.

The RAM 121b, the memory 121c, and the I/O port 121d are configured to be capable of exchanging data with the CPU 121a via an internal bus 121e. An input/output device 122 configured as, for example, a touch panel, is connected to the controller 280.

The memory 121c is constituted with, for example, a flash memory, a HDD (Hard Disk Drive), or the like. A control program for controlling the operations of the substrate processing apparatus, a process recipe in which the procedures, conditions, or the like of substrate processing (to be described later) are written, or the like are readably stored in the memory 121c.

The process recipe functions as a program that causes the controller 280 to execute each sequence in a substrate processing process (to be described later) to obtain desired results. Hereinafter, the process recipe and the control program may be generally and simply referred to as a “program.”

When the term “program” is used in the specification, it may indicate a case of including the process recipe alone, a case of including the control program alone, or a case of including both the process recipe and the control program. The RAM 121b is configured as a memory area (that is, a work area) in which programs or data read by the CPU 121a are temporarily stored.

The I/O port 121d is connected to the MFCs 320a to 320d, the valves 330a to 330d, the pressure sensor 245, the APC valve 244, the vacuum pump 246, the heater 207, the temperature sensor, the rotation mechanism 267, the elevator 115 described above, and the like.

The CPU 121a is configured to read and execute the control program from the memory 121c and also to read the process recipe from the memory 121c in response to an input of an operation command from the input/output device 122.

The CPU 121a is configured to control the flow rate adjustment operation of various gases by the MFCs 320a to 320d, the opening/closing operation of the valves 330a to 330d, and the opening/closing operation of the APC valve 244, based on the contents of the read process recipe. The CPU 121a is also configured to control the pressure adjustment operation by the APC valve 244 based on the pressure sensor 245, the start and stop of the vacuum pump 246, and the temperature adjustment operation of the heater 207 based on the temperature sensor. The CPU 121a is also configured to control the rotation and rotation speed adjustment operation of the boat 217 by the rotation mechanism 267, the raising/lowering operation of the boat 217 by the elevator 115, or the like.

The controller 280 is not limited to being configured by a dedicated computer, and may be configured as a general-purpose computer. For example, the controller 280 of this embodiment may be configured by preparing an external memory 123 storing the above-mentioned program, and providing the program in the general-purpose computer using the external memory 123. Examples of the external memory may include a magnetic disk such as a hard disk, an optical disc such as a CD, a magneto-optical disc such as a MO, a semiconductor memory such as a USB memory, and the like.

### <Substrate Processing Method>

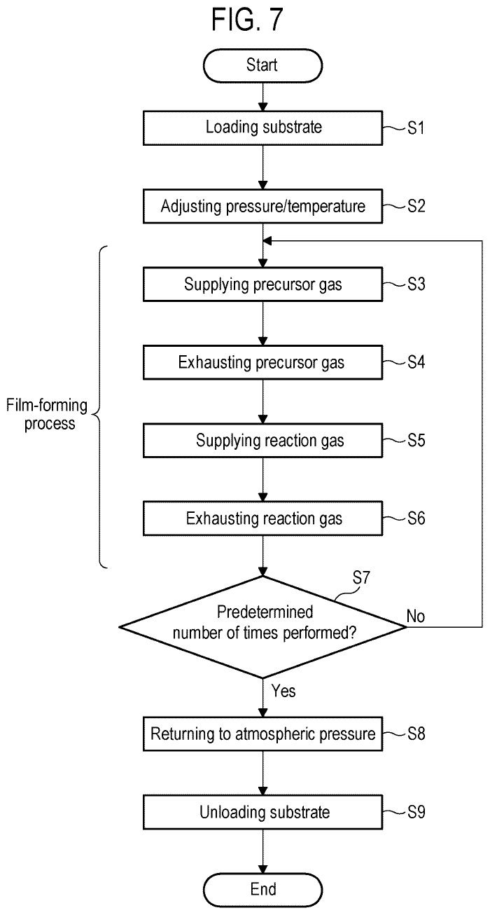

Next, a substrate processing method using the substrate processing apparatus 10 according to this embodiment will be described with reference to FIG. 7. In this embodiment, a cycle process in which a film-forming process is performed by alternately supplying a precursor gas and a reaction gas to a process chamber will be described as an example of a process of manufacturing a semiconductor device.

In the cycle process, a Si precursor gas is used as an example of a source, and a N-containing gas is used as a reactant, so that a Si nitride film (Si₃N₄ film, hereinafter also referred to as a SiN film) is formed on the wafer 200.

The SiN film is formed by performing a cycle a predetermined number of times (one or more times), the cycle including non-simultaneously performing a film-forming operation 1 in step S3, a film-forming operation 2 in step S4, a film-forming operation 3 in step S5, and a film-forming operation 4 in step S6 in FIG. 7.

The film-forming operation 1 is an operation of supplying the precursor gas to the wafer 200 in the inner tube 12. The film-forming operation 2 is an exhaust operation of removing the remaining precursor gas from the inner tube 12. The film-forming operation 3 is an operation of supplying the reaction gas such as the N-containing gas to the wafer 200 in the inner tube 12. The film-forming operation 4 is an exhaust operation of removing the remaining reaction gas from the inner tube 12.

First, in step S1 in FIG. 7, the wafer 200 is loaded into the boat 217. The boat 217 is loaded into the inner tube 12 so that the substrate is accommodated in the cylindrical portion of the inner tube 12. Subsequently, in step S2 in FIG. 7, after the boat 217 is loaded into the inner tube 12, the internal pressure and temperature of the inner tube 12 are adjusted. Subsequently, the four film-forming operations 1 to 4 are sequentially performed. Each operation will be described in detail below.

### (Film-Forming Operation 1)

In the film-forming operation 1, in step S3 in FIG. 7, the first injector is used to inject the precursor gas toward the wafer 200, while the main exhaust slit 236 and the two sub-exhaust slits 238 are used to exhaust the injected precursor gas to the outside of the cylindrical portion. Specifically, the flush supply in which the precursor gas and the carrier gas are discharged instantaneously, that is, in a relatively short time, from the gas nozzles 340a, 340b, 341a, and 341b, is performed one or more times. At this time, the assist gas may be injected from the gas nozzles 342a and 342c or the counter nozzle 343. When multiple flush supplies are performed intermittently, the flow rate of the assist gas may change in response to the flush supplies.

The precursor gas may be, for example, a Si- and halogen-containing gas. The Si- and halogen-containing gas may be, for example, an inorganic chlorosilane-based gas such as a tetrachlorosilane (SiCl₄, abbreviation: STC) gas, a hexachlorodisilane (Si₂Cl₆, abbreviation: HCDS) gas, or an octachlorotrisilane (Si₃Cl₈, abbreviation: OCTS) gas. One or more of these gases may be used as the Si- and halogen-containing gas.

In the present disclosure, the term “large flow rate” means a state in which a mass flow rate [kg/s] is 8×10⁻⁴ kg/s or more. The mass flow rate [kg/s] of 8×10⁻⁴ kg/s or more corresponds to, for example, a volumetric flow rate [slm] of HCDS gas of about 4 slm or more. Moreover, the mass flow rate [kg/s] of 8×10⁻⁴ kg/s or more corresponds to a volumetric flow rate [slm] of N₂ gas of about 38 slm or more. In this specification, 1 [slm] is defined as 1 [L/m]. At the large flow rate, various difficulties in gas supply, such as a vortex and a return flow, tend to occur in the process chamber 201.

The volumetric flow rate [slm] is calculated by “mass flow rate/density of gas species.” Therefore, the volumetric flow rate may be used as a flow rate applicable to the present disclosure regardless of the gas species. Typical volumetric flow rates of large flow rates used in applicable film species are, for example, about 5.5 slm or more for titanium tetrachloride (TiCl₄), about 30 slm or more for oxygen (O₂), about 15 slm or more for trimethylaluminum (TMA), and about 65 slm or more for NH₃.

The intermittent flush supply operation causes the precursor gas to be adsorbed onto the surface of the wafer 200. A film containing Si is formed on a base film of the wafer 200 by the adsorption. The substrate processing method according to this embodiment may be implemented by steps S1 and S3 described above.

### (Film-Forming Operation 2)

In the film-forming operation 2, in step S4 in FIG. 7, first, the supply of the precursor gas and the carrier gas is stopped. Subsequently, by controlling an exhaust pump such as the vacuum pump 246 and the APC valve 244, or the like, the precursor gas is vacuum-exhausted so that the internal pressure of the reaction tube 203 becomes a predetermined pressure (that is, vacuum degree). By the vacuum-exhaust, the precursor gas remaining in the inner tube 12 is exhausted from the inner tube 12 to the outside. In addition, in the film-forming operation 2, when an inert gas, for example, a N₂ gas, is supplied as a purge gas into the inner tube 12, the effect of exhausting the remaining precursor gas is further enhanced.

### (Film-Forming Operation 3)

In the film-forming operation 3, in step S5 in FIG. 7, the second injector is used to supply the reaction gas into the inner tube 12. The reaction gas may be, for example, a N-containing gas, a non-Si-containing gas, an oxidizing gas, or a reducing gas such as hydrogen (H₂). In step S5, for example, an NH₃ gas is supplied as the reaction gas into the inner tube 12, while being exhausted from a plurality of exhaust slits. The supply of the N-containing gas causes a reaction between the Si-containing film on the base film of the wafer 200 and the N-containing gas. A SiN film is formed on the wafer 200 by the reaction. Alternatively, when a mixed gas of O₂ and H₂ is used as the reaction gas, SiO₂ is formed.

### (Film-Forming Operation 4)

In the film-forming operation 4, in step S6 in FIG. 7, after forming the film, by controlling the exhaust pump such as the vacuum pump 246, the APC valve 244, and the like, the reaction gas is vacuum-exhausted so that the internal pressure of the reaction tube 203 becomes a predetermined pressure (vacuum degree). By the vacuum-exhaust, the N₂-containing gas remaining in the inner tube 12 after contributing to the film formation is exhausted from the inner tube 12 to the outside. In addition, in the film-forming operation 4, when an inert gas, for example, a N₂ gas used as a carrier gas, is supplied as a purge gas into the inner tube 12, the effect of exhausting the reaction gas of the remaining N₂-containing gas from the inner tube 12 is further enhanced.

With the above-described film-forming operations 1 to 4 as one cycle, in step S7 in FIG. 7, a SiN film having a predetermined thickness may be formed on the wafer 200 by performing the cycle including the film-forming operations 1 to 4 a predetermined number of times. In this embodiment, the film-forming operations 1 to 4 are repeated multiple times. In the present disclosure, the film-forming operations 1 to 4 may be performed one at a time without being repeated.

In the film formation by the cycle process like this example, among a plurality of process gases, one gas that is dominant in film quality, particularly uniformity, may be present. For example, when it is important for good step coverage to uniformly adsorb a chlorosilane-based gas of the precursor gas onto adsorption sites in the fine structure, only the precursor gas may be supplied in a planar manner by the first injector. As a result, both the flow velocity and partial pressure of the precursor gas or intermediate may be maintained within a predetermined range on the surface of the wafer. On the other hand, the exposure of the wafer to the reaction gas does not require the same uniformity as the precursor gas.

After the above-described film-forming process is completed, in step S8 in FIG. 7, the internal pressure of the inner tube 12 is returned to the normal pressure (that is, the atmospheric pressure). Specifically, for example, an inert gas such as a N₂ gas is supplied into and exhausted from the inner tube 12. As a result, the interior of the inner tube 12 is purged with the inert gas, and a gas and the like remaining in the inner tube 12 are removed from the interior of the inner tube 12. After that, the internal atmosphere of the inner tube 12 is replaced with the inert gas, and the internal pressure of the inner tube 12 is returned to the normal pressure.

Then, in step S9 in FIG. 7, when the wafer 200 is unloaded from the inner tube 12, the substrate processing according to this embodiment is completed. The above series of operations constitute the method of manufacturing a semiconductor device using the wafer 200 according to this embodiment.

When the term “wafer” is used in this specification, it may refer to “a wafer itself” or “a stacked body of a wafer and certain layers or films formed on a surface of the wafer.” When the phrase “a surface of a wafer” is used in this specification, it may refer to “a surface of a wafer itself” or “a surface of a certain layer formed on a wafer.” When the expression “a certain layer is formed on a wafer” is used in this specification, it may mean that “a certain layer is formed directly on a surface of a wafer itself” or that “a certain layer is formed on a layer formed on a wafer.” When the term “substrate” is used in this specification, it may be synonymous with the term “wafer.”

### (Analysis Examples)

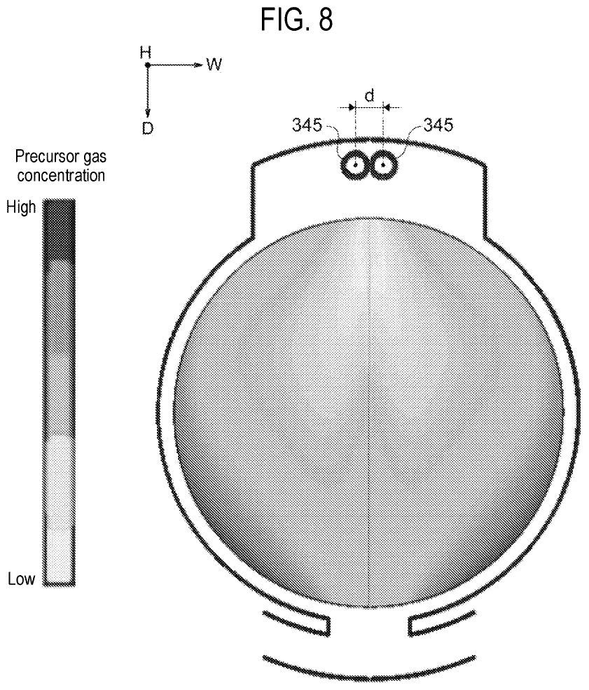

Next, first to third analysis examples for confirming characteristics of the substrate processing apparatus according to this embodiment will be described with reference to FIGS. 8 to 12E.

### (First Analysis Example)

First, a first analysis example in which a distance between centers of two straight pipe nozzles is analyzed will be described. FIG. 8 illustrates a distribution of a concentration of the precursor gas inside the cylindrical portion when the distance between centers d of two gas nozzles 345 corresponding to the gas nozzles 340b and 341b of the substrate processing apparatus according to this embodiment is 22 mm. In the first analysis example, the substrate processing apparatus is provided with only a main exhaust slit, without a sub-exhaust slit.

As shown in FIG. 8, even if no sub-exhaust slit is provided, by providing the two gas nozzles 345, unevenness of the distribution of the concentration of the precursor gas on the substrate is suppressed as a whole as compared to a case where there is only one gas nozzle 345. FIG. 8 illustrates a state in which a portion with a relatively high concentration of the precursor gas is present on outer edges of both sides of the substrate and on the side of the main exhaust slit in the depth direction D of the apparatus.

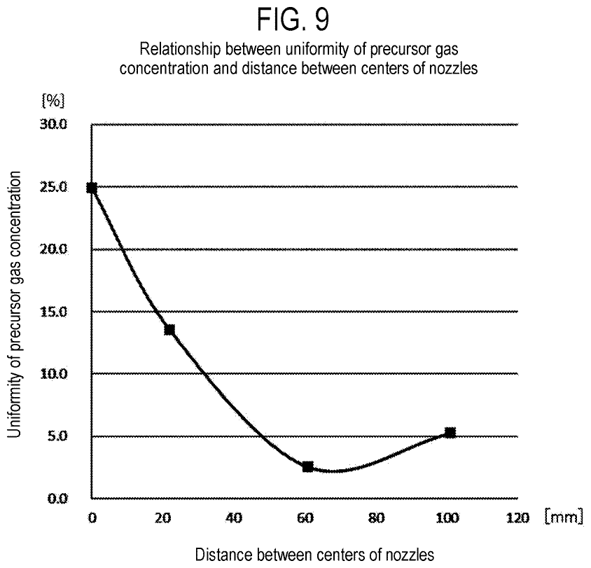

Further, FIG. 9 illustrates an analysis result of a relationship between the uniformity of the concentration of the precursor gas and the distance between centers d of the two gas nozzles. Each gas nozzle has three injection holes. As shown in FIG. 9, the uniformity of the concentration of the precursor gas on the substrate is expressed as the standard deviation [±%] relative to the average concentration [%]. The average concentration [%] is the concentration of the precursor gas per unit area on the entire substrate surface.

In addition, in FIG. 9, a value of 25% is plotted as the uniformity of the concentration of the precursor gas when the distance between centers d of the two gas nozzles is 0 mm. When the distance between centers d is 0 mm, it means that there is one gas nozzle.

As shown in FIG. 9, when the distance between centers d of the two gas nozzles is 20 mm or more and 100 mm or less, the standard deviation is suppressed to about 14% or less, finding that the uniformity of the concentration of the precursor gas may be improved. When the distance between centers d exceeds 100 mm, the dimensions of the supply buffer become large, resulting in a concern that the inner tube becomes bulky.

In addition, when the distance between centers d of the two gas nozzles is 40 mm or more and 100 mm or less, the standard deviation is suppressed to about 7% or less, finding that the uniformity of the concentration of the precursor gas may be further improved. Further, when the distance between centers d of the two gas nozzles is 60 mm or more and 80 mm or less, the standard deviation is suppressed to about 3% or less, finding that the uniformity of the concentration of the precursor gas may be even further improved.

### (Second Analysis Example)

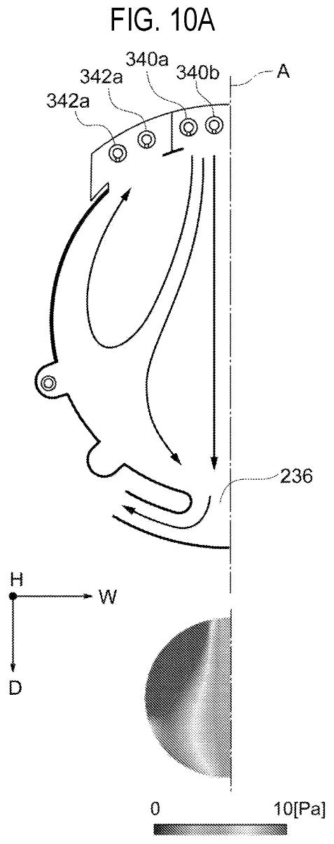

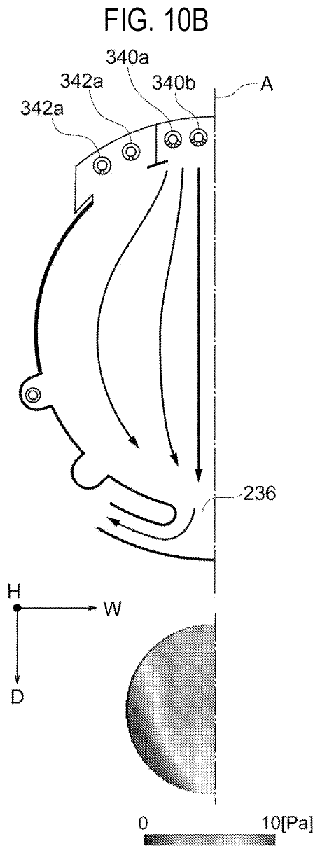

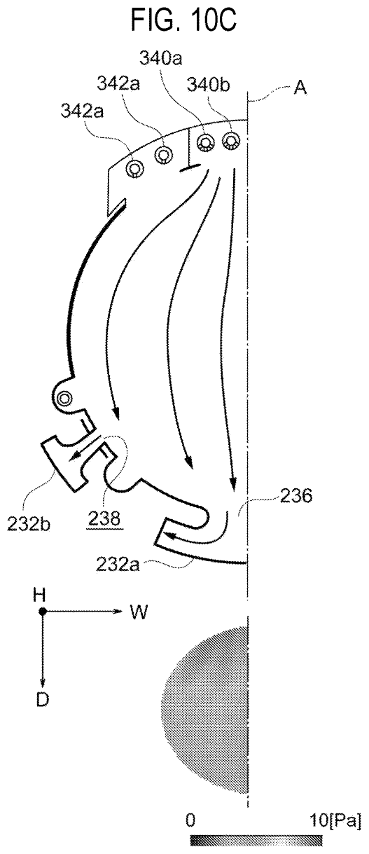

Next, a second analysis example in which a flow of the precursor gas inside the cylindrical portion of the inner tube and a distribution of the partial pressure [Pa] of the intermediate are analyzed will be described. In the second analysis example, an inorganic chlorosilane-based gas is used as the precursor gas, and the intermediate is SiCl₂ generated by decomposition of the precursor gas. The precursor gas is supplied to the wafer at a large flow rate by four gas nozzles. In FIGS. 10A to 10C, since the flow of the precursor gas is symmetrical across the virtual plane A, only the state on the left side is illustrated and the state on the right side is omitted.

FIG. 10A illustrates the flow and partial pressure distribution of the precursor gas in an analysis model in which the gas nozzles 340a and 340b each have one column of injection holes and only one main exhaust slit 236 in the substrate processing apparatus according to this embodiment. That is, the pair of sub-exhaust slits 238 are not provided.

In the analysis model of FIG. 10A, as shown in the upper stage, a return flow, that is, a vortex, returning from the gas nozzles 340a and 340b to the vicinity of the gas nozzle 342a during the supply of the precursor gas, is formed. In addition, as shown in the lower stage of FIG. 10A, a portion in which the partial pressure of the intermediate is high to be about 10 Pa is formed in the wafer at positions corresponding to both sides of the virtual plane A over the entire depth direction D, and a concentration gradient is distributed over the entire wafer. The high intermediate partial pressure suggests that the flow velocity is relatively low.

Further, FIG. 10B illustrates a flow and partial pressure distribution of the precursor gas in an analysis model in which the gas nozzles 340a and 340b each have three columns of injection holes and only one main exhaust slit 236 in the substrate processing apparatus according to this embodiment. Other analysis conditions are the same as those in FIG. 10A.

In the analysis model of FIG. 10B, as shown in the upper stage, no return flow is formed. In addition, as shown in the lower stage of FIG. 10B, the partial pressure concentration of the intermediate is relatively uniformly distributed except for the side portion in the width direction W, which is improved as compared to the case of FIG. 10A. Specifically, in the positions corresponding to both sides of the wafer and the portions on the gas nozzles 340a and 340b side in the depth direction D, the partial pressure concentration of the precursor gas is suppressed to 10 Pa or less.

Further, FIG. 10C illustrates a flow and partial pressure distribution of the precursor gas in an analysis model in which the gas nozzles 340a and 340b each have three columns of injection holes, one main exhaust slit 236, and two sub-exhaust slits 238 in the substrate processing apparatus according to this embodiment. Other analysis conditions are the same as those in FIG. 10A.

In the analysis model of FIG. 10C in which the two sub-exhaust slits 238 are added, no return flow is formed, as shown in the upper stage. It is also found that a flow of the precursor gas flowing at a position corresponding to the vicinity of the outer edge of the side of the wafer is formed by the two sub-exhaust slits 238. In addition, as shown in the lower stage of FIG. 10C, a deviation of the partial pressure of the intermediate is clearly reduced as compared to the cases of FIGS. 10A and 10B.

### (Third Analysis Example)

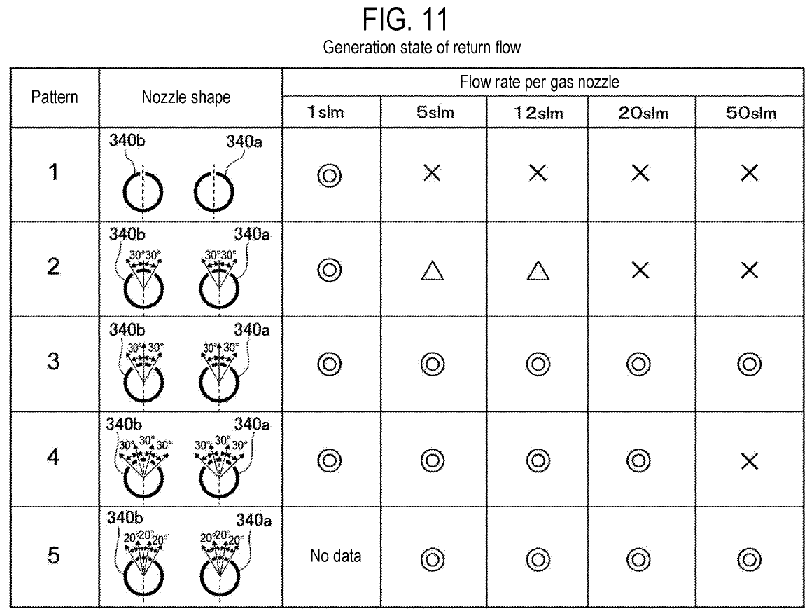

Next, a third analysis example in which the return flow inside the cylindrical portion of the inner tube is analyzed will be described. As shown in FIG. 11, in the third analysis example, the presence or absence of the return flow is evaluated in each pattern in which the shapes of the injection holes are different from each other when the precursor gas is injected from the two gas nozzles 340a and 340b. The analysis conditions of the simulation in the third analysis example, such as a pressure, a temperature, and a gas type, are set to imitate those used in the actual film-forming process.

As shown in FIG. 11, the presence or absence of the return flow is evaluated in three situations “⊚”, “Δ”, and “x”. “⊚” means that there was no or almost no return flow. “Δ” means that a weak return flow is observed. “x” means that a strong return flow is present.

In addition, in the third analysis example, five patterns are set according to the shapes of the gas nozzles 340a and 340b that are different from each other. In a first pattern, the number of injection holes in each of the two gas nozzles 340a and 340b is one, and the diameter of the injection hole is 4.6 mm.

In a second pattern, the number of injection holes in each of the two gas nozzles 340a and 340b is two along the circumferential direction of the gas nozzles 340a and 340b. In the second pattern, the injection holes are arranged so that an angle between the injection direction of each injection hole and a direction from the center of the gas nozzles 340a and 340b toward the center of the wafer is 30 degrees in a plan view. The diameter of the injection hole is 1.9 mm.

In a third pattern, the number of injection holes in each of the two gas nozzles 340a and 340b is three along the circumferential direction of the gas nozzles. In the third pattern, the injection holes are arranged so that an angle between adjacent injection holes is 30 degrees in a plan view. In addition, the injection direction of the central injection hole among the three injection holes is aligned in the direction from the center of the gas nozzles 340a and 340b toward the center of the wafer in a plan view. The diameter of the injection hole is 1.9 mm.

In a fourth pattern, the number of injection holes in each of the two gas nozzles 340a and 340b is four along the circumferential direction of the gas nozzles. In the fourth pattern, the injection holes are arranged so that an angle between adjacent injection holes is 30 degrees in a plan view. In addition, the injection holes are arranged so that an angle between the injection direction of the central two injection holes among the four injection holes and a direction from the center of the gas nozzles 340a and 340b toward the center of the wafer is 30 degrees in a plan view. The diameter of the injection hole is 1.9 mm.

In a fifth pattern, the number of injection holes in each of the two gas nozzles 340a and 340b is four along the circumferential direction of the gas nozzle 340b. In the fifth pattern, the injection holes are arranged so that an angle between adjacent injection holes is 20 degrees in a plan view. In addition, the injection holes are arranged so that an angle between the injection direction of the central two injection holes among the four injection holes and the direction from the center of the gas nozzles 340a and 340b toward the center of the wafer is 20 degrees in a plan view.

That is, the injection range centered on the direction from the center of the gas nozzles 340a and 340b toward the center of the wafer in the fourth pattern is set to be wider than the injection range in the fifth pattern. The diameter of the injection hole is 1.9 mm.

In addition, the inner diameter and thickness of the cylinder of the gas nozzles 340a and 340b are set to be the same throughout the first to fifth patterns. In the first pattern, a partition wall is provided between the central portion 222b of the supply buffer 222 where the gas nozzles 340a and 340b are arranged and the cylindrical portion of the inner tube 12, and a slit that opens to face the injection hole is provided, as in the supply slit 235a in FIG. 3. On the other hand, in all of the second to fifth patterns, as in this embodiment shown in FIG. 3, no partition wall is provided between the central portion 222b of the supply buffer 222 in which the gas nozzles 340a and 340b are arranged and the cylindrical portion of the inner tube 12.

In the third analysis example, an analysis is performed with five different flow rates per gas nozzle: 1 slm, 5 slm, 12 slm, 20 slm, and 50 slm. As a result of the analysis, as shown in FIG. 11, in the first pattern, a return flow is continuously present at flow rates per gas nozzle of 5 slm, 12 slm, 20 slm, and 50 slm. In the second pattern, it was found that the smaller the flow rate per gas nozzle, the more the occurrence of the return flow is suppressed.

Further, in the third, fourth, and fifth patterns, it is found that the return flow does not occur except when the flow rate per gas nozzle is 50 slm in the fourth pattern. In the fourth pattern, when the flow rate per gas nozzle is 50 slm, since the injection range centered on the direction from the center of the gas nozzles 340a and 340b toward the center of the wafer is wider than the injection range in the fifth pattern, the flow of the precursor gas from the injection hole collides with the sidewall of the supply buffer close to the injection hole. For this reason, the return flow exists continuously.

Further, even when the flow rate per gas nozzle is 50 slm in the fourth pattern, another analysis example is performed in which other structures such as the sidewall of the supply buffer are not arranged in the vicinity of the gas nozzles 340a and 340b. As a result, it is found that the blockage of the flow of the precursor gas by other structures is avoided.

### <Modifications>

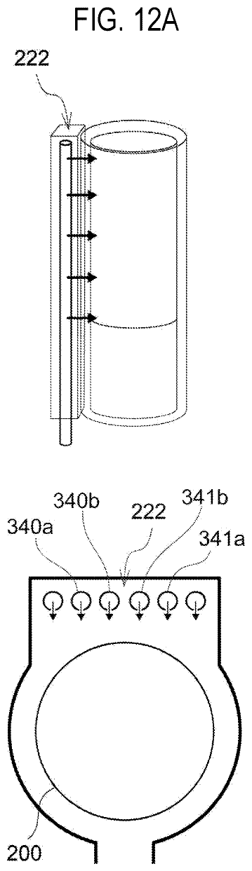

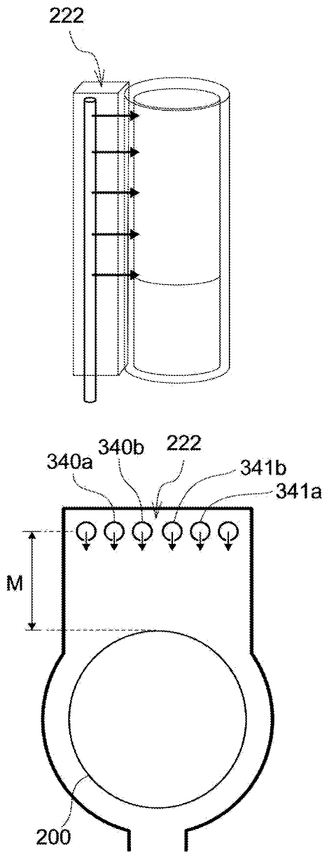

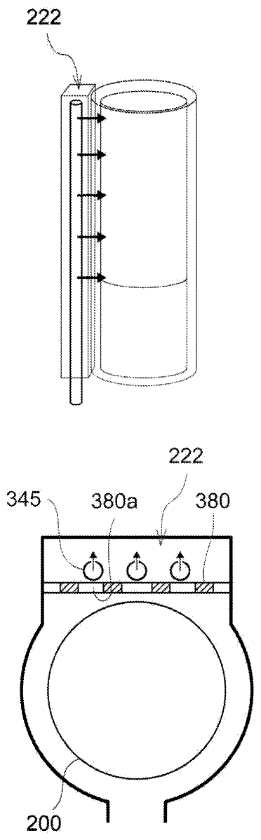

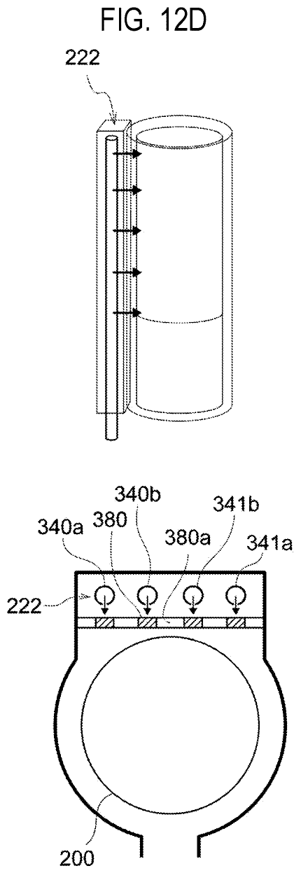

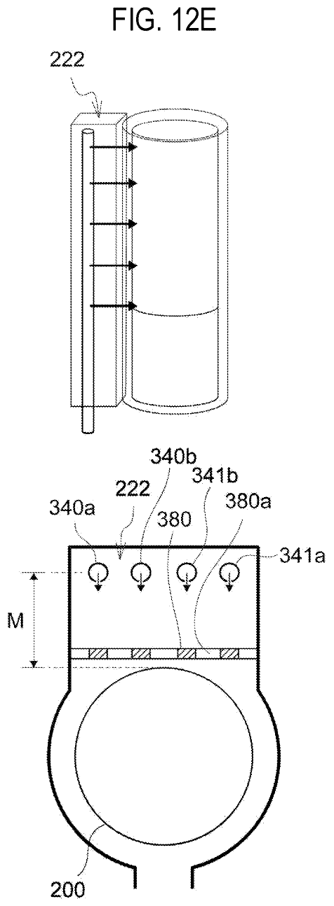

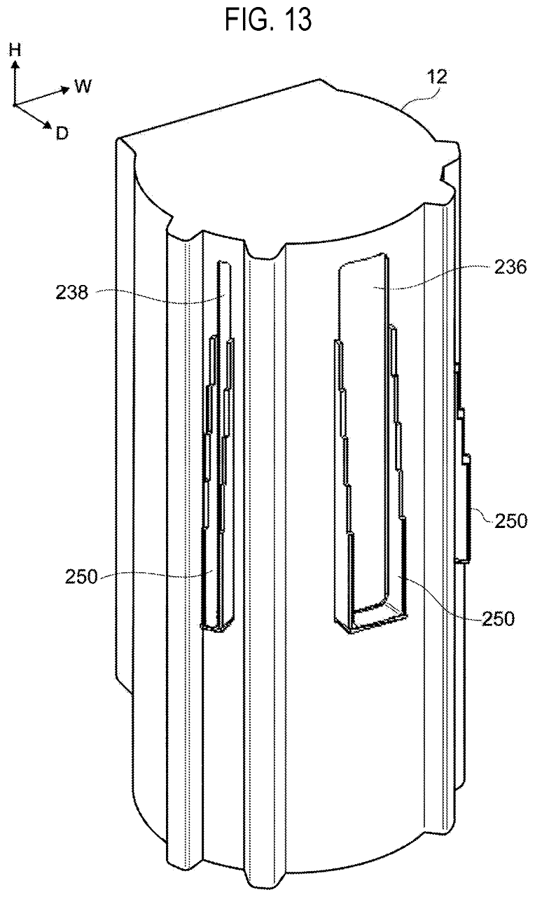

Next, substrate processing apparatuses according to first to sixth modifications will be described with reference to FIGS. 12A to 13. In the first to sixth modifications, an inner structure of the supply buffer 222 is different from that of this embodiment.

### (First Modification)

As shown in FIG. 12A, in the present disclosure, the number of gas nozzles 340a, 340b, 341a, and 341b constituting the first injector may be changed as appropriate to one or more. FIG. 12A illustrates the substrate processing apparatus according to the first modification, in which six gas nozzles corresponding to the gas nozzle 340a and the like constituting the first injector are provided. The first modification may also achieve the same effects as in this embodiment.

### (Second Modification)

As shown in FIG. 12B, in the second modification, a plurality of gas nozzles corresponding to the gas nozzle 340a and the like are arranged to be spaced apart from the wafer 200. Specifically, the supply buffer 222 is configured so that a certain distance M is formed between the center of each gas nozzle and the wafer 200. In this modification, the certain distance M is preferably, for example, at least twice and at most 10 times the length of the Kolmogorov length.

When the certain distance M is less than twice the Kolmogorov length of the gas flow from the gas nozzle, the precursor gas will hit the wafer 200 without sufficient homogenization of the flow. When the certain distance M exceeds 10 times the Kolmogorov length, the substrate processing apparatus may become too large. In this modification, the certain distance may be set arbitrarily.

The second modification may also achieve the same effects as in this embodiment. Further, in the second modification, by arranging the plurality of gas nozzles away from the wafer 200, mixing of precursor gases is promoted before the precursor gases injected from the plurality of gas nozzles reach the wafer 200. Therefore, the precursor gases with promoted mixing may be sent onto the surface of the wafer 200.

### (Third Modification)

As shown in FIG. 12C, in the third modification, the injection holes of the plurality of gas nozzles 345 corresponding to the gas nozzles 340a and the like open toward the sidewall opposite the wafer 200 (that is, the upper side in FIG. 12C). The third modification may also achieve the same effects as in this embodiment. Further, in the third modification, by opening the injection holes of the plurality of gas nozzles 345 toward the sidewall opposite the wafer 200, the injected precursor gas collides with the sidewall opposite the wafer 200. The precursor gas that collides with the sidewall opposite the wafer 200 heads toward a ventilation slit 380a of a partition wall 380 provided between the gas nozzles 345 and the wafer 200. The precursor gas reaches the wafer 200 via the ventilation slit 380a.

The ventilation slit 380a of the third modification is an example of a ventilation port having an opening. In the present disclosure, the shape of the opening of the ventilation port formed in the partition wall is not limited to a slit shape, and may be changed arbitrarily, for example, to a hole shape. In the present disclosure, the ventilation port is an example of a ventilator formed between the gas nozzles 345 and the wafer 200 to orient the precursor gas toward the wafer 200. Further, in the present disclosure, the ventilator is not limited to the ventilation port of the partition wall. For example, a ventilator having a tubular overall shape and an internal gas flow path may be provided as the ventilator.

Therefore, in the third modification, mixing of precursor gases is promoted after the precursor gases are injected from the gas nozzles 345 until they reach the wafer 200. As a result, the precursor gases with promoted mixing may be sent onto the surface of the wafer 200.

### (Fourth Modification)

As shown in FIG. 12D, in the fourth modification, the injection holes of the plurality of gas nozzles corresponding to the gas nozzle 340a and the like open toward the sidewall provided between the gas nozzles and the wafer 200. The fourth modification may also achieve the same effects as in this embodiment. Further, in the fourth modification, by opening the injection holes of the plurality of gas nozzles toward the partition wall 380 provided between the gas nozzles and the wafer 200, the injected precursor gas collides with the partition wall 380.

The precursor gas that collides with the partition wall 380 reaches the wafer 200 via the ventilation slit 380a of the partition wall 380. Therefore, mixing of precursor gases is promoted after the precursor gases are injected from the gas nozzles 340b until they reach the wafer 200. As a result, the precursor gases with promoted mixing may be sent onto the surface of the wafer 200.

### (Fifth Modification)

In addition, in the present disclosure, the configurations of the first to fourth modifications may be partially combined with each other. FIG. 12E illustrates a fifth modification in which the configurations of, for example, the second modification and the fourth modification are combined with each other. That is, in a supply buffer 222 according to the fifth modification, similarly to the second modification, the plurality of gas nozzles are arranged to be spaced apart from the wafer 200 so that a certain distance M is formed between the center of the gas nozzle and the wafer 200.

Further, in the fifth modification, similarly to the fourth modification, the partition wall 380 having the ventilation slit 380a is provided between the gas nozzle and the wafer 200, and the injection holes of the plurality of gas nozzles corresponding to the gas nozzle 340a and the like open toward the partition wall 380 having the ventilation slit 380a. Therefore, in addition to the same effects as in this embodiment, the fifth modification may achieve both the effects of the second modification and the effects of the fourth modification.

### (Sixth Modification)

As shown in FIG. 13, in a substrate processing apparatus according to the sixth modification, the main exhaust slit 236 and the pair of sub-exhaust slits 238 are both rectangular in shape. In the sixth modification, fins 250 and 251 protruding from the sidewall of the cylindrical portion toward the outer tube 14 are provided as an exhaust flow rate adjuster along right, left and bottom edges of the main exhaust slit 236 and the pair of sub-exhaust slits 238, respectively.

A protrusion length of the fins 250 provided on the circumference of the main exhaust slit 236 decreases along the axial direction of the cylindrical portion from the upper side in FIG. 13, which is the opposite side of the exhaust port 230, to the lower side in FIG. 13 where the exhaust port 230 is located. The protrusion length of the fins 251 provided on the circumference of the sub-exhaust slit 238 decreases along the axial direction of the cylindrical portion from the upper side in FIG. 13, which is the opposite side of the exhaust port 230, to the lower side in FIG. 13 where the exhaust port 230 is located.

The sixth modification may also achieve the same effects as in this embodiment. Further, in the sixth modification, the fins 250 may equalize the flow rate of the precursor gas exhausted between the substrates stacked in multiple stages along the axial direction of the cylindrical portion, that is, equalize the conductance in the vertical direction. Details of the operation and effects of the sixth modification will be described later.

Further, in FIG. 13, the fins 250 are formed in a stepped shape using a plate-like member having five plate-like portions with a long protrusion length from the top to the bottom, but in the present disclosure, the shape of the exhaust flow rate adjuster is not limited to the stepped shape. For example, in the present disclosure, the exhaust flow rate adjuster may be configured using a plate-like member having plate-like portions whose protrusion length gradually becomes shorter as they approach the main exhaust port. In addition, the exhaust flow rate adjuster is not limited to the plate-like member, and may be configured using a block-like member, an annular member, or the like.

### (Seventh Modification)

As shown in FIG. 10C, a substrate processing apparatus according to the seventh modification includes a main exhaust buffer 232a formed to air-tightly cover the main exhaust slit 236 from the outside of the inner tube 12, and two sub-exhaust buffers 232b formed separately from the main exhaust buffer to similarly cover each of the two sub-exhaust slits 238 from the outside of the inner tube 12. Each of the main exhaust buffer 232a and the sub-exhaust buffer 232b is connected to an exhaust duct 231.

Like the supply buffer 222, the main exhaust buffer 232a and the sub-exhaust buffer 232b are formed on the outside of the inner tube to extend in the axial direction of the reaction tube along the distribution of the corresponding main exhaust slits 236 and sub-exhaust slits 238. The main exhaust buffer 232a alleviates the internal pressure gradient and provides uniform exhaust to the wafer 200 in cooperation with the main exhaust slit 236. This also holds true in the sub-exhaust buffer 232b.

The main exhaust buffer 232a corresponds to a main exhauster configured to send the precursor gas to the outside in the present disclosure. The two sub-exhaust buffers 232b correspond to two sub-exhausters configured to send the precursor gas to the outside in the present disclosure. In the present disclosure, the main exhauster is not limited to the main exhaust buffer, and may be any main exhaust space through which the internal pressure gradient may be alleviated. Similarly, in the present disclosure, the sub-exhauster is not limited to the sub-exhaust buffer, and may be any sub-exhaust space through which the internal pressure gradient may be alleviated.

The seventh modification may also achieve the same effects as in this embodiment. In the seventh modification, by further providing the main exhaust buffer 232a or the like, the outer tube 14 is no longer necessary, and a process container with a single tube structure may be adopted. In this context, the term “process tube” means each of the inner tube 12 and the outer tube 14, and may particularly include a single tube which has the same shape and pressure resistance strength as the inner tube 12 and is used alone.

### (Actions and Effects)

This embodiment provides one or more of the following effects.

The substrate processing apparatus 10 according to this embodiment is provided with the reaction tube 203 including the inner tube 12 and the outer tube 14, the supply buffer 222 provided in the cylindrical portion of the inner tube 12, the four gas nozzles 340a, 340b, 341a and 341b provided in the supply buffer 222, and the two sub-exhaust slits 238 provided in the cylindrical portion.

The two sub-exhaust slits 238 are formed in the sidewall of the cylindrical portion and open with the virtual plane A, which is set to pass through the circumferential center of the cylindrical portion at the boundary between the supply buffer 222 and the cylindrical portion and the axis of the cylindrical portion in a plan view, sandwiched from both sides. That is, the two sub-exhaust slits 238 face both sides of the wafer 200 which sandwich the virtual plane A.

Therefore, the precursor gas injected from the four gas nozzles 340a, 340b, 341a, and 341b is promoted to flow not only toward the center of the wafer 200 in a plan view, but also toward both sides of the wafer 200. As a result, the uniformity of the flow of the precursor gas on the surface of the wafer 200 during the film-forming process may be improved.

In addition, in this embodiment, when improving the uniformity of the flow of the precursor gas, it is only necessary to form the two sub-exhaust slits 238 in the cylindrical portion which sandwich the virtual plane A from both sides. This eliminates a need to provide a separate member. As a result, the substrate processing apparatus 10 may have a relatively low-cost and compact configuration.

In addition, in this embodiment, one main exhaust slit 236 is provided in the sidewall of the cylindrical portion on the opposite side of the supply buffer 222 with respect to the center C1 of the wafer 200. In addition, two sub-exhaust slits 238 are arranged to be spaced apart from the main exhaust slit 236 at the same height as the main exhaust slit 236 and sandwich the main exhaust slit 236. In addition, in a plan view, an measure of angle between the virtual plane A and each of the first virtual lines L1 connecting the center of the sub-exhaust slit 238 and the center C1 of the wafer 200 is an obtuse angle, preferably in the range 110 to 150 degrees. In addition, the width of each of the two sub-exhaust slits 238 in the circumferential direction of the cylindrical portion is smaller than the width of the main exhaust slit 236.

The precursor gas is further dispersed by the main exhaust slit 236 and the two sub-exhaust slits 238. Thus, a region where the flow of the precursor gas decreases around the wafer 200 is reduced. This may further improve the uniformity of the flow of the precursor gas on the surface of the wafer 200.

In addition, in this embodiment, the four gas nozzles 340a, 340b, 341a, and 341b are configured to be arranged along the circumferential direction of the cylindrical portion and to be capable of supplying the same precursor gas. Each of the four gas nozzles 340a, 340b, 341a, and 341b has the outward pipe and the return pipe through which the precursor gas flows, and is a return nozzle having the injection hole 234 which injects the same precursor gas by communicating the upper end of the outward pipe with the upper end of the return pipe.

In this embodiment, the precursor gas is further dispersed by the four gas nozzles 340a, 340b, 341a, and 341b. In addition, the four gas nozzles 340a, 340b, 341a, and 341b may be simply and easily configured by two return nozzles.

In addition, in this embodiment, by the four gas nozzles 340a, 340b, 341a, and 341b arranged along the circumferential direction of the cylindrical portion, a flow rate of a gas injected toward the periphery of the wafer 200 is larger than that of a gas injected toward the center C1 of the wafer 200. Thus, the region where the flow of the precursor gas is slow around the wafer 200 is reduced. This may further improve the uniformity of the flow of the precursor gas on the surface of the wafer 200.

In addition, in this embodiment, the four gas nozzles 340a, 340b, 341a, and 341b have three or more injection holes 234 arranged along the circumferential direction of the cylindrical portion in the plane parallel to the surface of the wafer 200.

Since the precursor gas is injected radially from the three or more injection holes 234, the region where the flow of the precursor gas decreases around the wafer 200 is reduced. This may further improve the uniformity of the flow of the precursor gas on the surface of the wafer 200.

In addition, in this embodiment, the four gas nozzles 340a, 340b, 341a, and 341b and the two sub-exhaust slits 238 are configured in symmetry to the virtual plane A. This further improves the uniformity of the flow of the precursor gas on the surface of the wafer 200.

In addition, in this embodiment, the plurality of wafers 200 are arranged inside the cylindrical portion along the axial direction of the cylindrical portion. In addition, the four gas nozzles 340a, 340b, 341a, and 341b are configured to be arranged along the circumferential direction of the cylindrical portion to be capable of supplying the same precursor gas. In addition, each of the four gas nozzles 340a, 340b, 341a, and 341b includes the outward pipe and the return pipe through which the precursor gas flows. The four gas nozzles 340a, 340b, 341a, and 341b are formed by two return nozzles which inject the same precursor gas by communicating the upper end of the outward pipe with the upper end of the return pipe. In addition, the two return nozzles 340 and 341 are arranged such that their return pipes are adjacent to each other and their outward pipes are arranged to be spaced apart from each other. In addition, each of the outward pipes and return pipes of the two return nozzles 340 and 341 has three or more columns of injection holes 234 which extend along the longitudinal direction of the return nozzle. The injection holes 234 inject the precursor gas radially in a plan view.

By arranging the outward pipe with a relatively high internal pressure outside the center C1 of the wafer 200, a large amount of gas may be supplied to the outer periphery of the wafer 200 where the gas flow rate and gas concentration tend to be insufficient in radial injection. This makes it possible to suppress the occurrence of a return flow of the precursor gas.

In addition, in this embodiment, the tanks 322b and 322c are provided which are connected to the four gas nozzles 340a, 340b, 341a, and 341b, store the precursor gas alone without being mixed with the carrier gas, and supply the stored precursor gas to the four gas nozzles 340a, 340b, 341a, and 341b in a pulse-like manner almost simultaneously. In addition, the total instantaneous maximum flow rate of the precursor gas injected in the pulse-like manner from each of the four gas nozzles 340a, 340b, 341a, and 341b is 5 slm or more.

Here, in the case where the flush supply is performed, when the total instantaneous maximum flow rate of the precursor gas is small, a film-forming gas may receive sufficient heat and may be altered. On the other hand, when the gas is supplied at a large flow rate, it is possible to supply a fresh gas to the wafer 200 without receiving much heat. Therefore, this embodiment in which the precursor gas is flush-supplied at 5 slm or more is advantageous in that the quality of a film formed may be further improved.

In addition, in this embodiment, the diameter R1 of the injection hole 234, which injects the precursor gas from the center C1 of the wafer 200 toward the outermost side thereof, among the three or more injection holes 234, may be larger than the diameter R2 of the other injection holes 234. Therefore, the flow rate of the exhausted precursor gas is more uniform. As a result, the film inter-surface uniformity between the surfaces of the plurality of wafers 200 is improved.

In addition, in this embodiment, a space through which the precursor gas may move linearly along the injection direction is formed between the wafer 200 and one of the three or more injection holes 234 which injects the precursor gas toward the outermost side of the wafer 200 in a plan view. That is, no other structure is provided as an obstacle that blocks the flow of the precursor gas before the precursor gas reaches the wafer 200. The flow rate of the exhausted precursor gas is more uniform. Thus, the film inter-surface uniformity between the surfaces of the plurality of wafers 200 is improved.

In addition, in this embodiment, the reaction tube 203 further includes the outer tube 14 which surrounds the cylindrical portion to form the exhaust space S between the cylindrical portion and the outer tube 14. The outer tube 14 has the exhaust port 230 and a pair of sub-exhaust ports (not shown) that communicate the exhaust space S with the outside of the reaction tube 203. Therefore, the precursor gas passes through the exhaust space and is exhausted to the outside from the exhaust port 230 and the pair of sub-exhaust ports. Thus, the region where the flow of the precursor gas decreases around the wafer 200 is reduced. Therefore, the uniformity of the flow of the precursor gas on the surface of the wafer 200 may be further improved.

In addition, in this embodiment, the opening width along the circumferential direction of the cylindrical portion of one main exhaust slit 236 becomes narrower from the side opposite the exhaust port 230 toward the exhaust port 230 along the axial direction of the cylindrical portion. In addition, the opening width along the circumferential direction of each of the two sub-exhaust slits 238 becomes narrower from the side opposite the pair of sub-exhaust ports toward the pair of sub-exhaust ports along the axial direction of the cylindrical portion. Therefore, the flow rate of the exhausted precursor gas is more uniform between the wafers 200 stacked in multiple stages along the axial direction. Thus, the film inter-surface uniformity between the surfaces of the plurality of wafers 200 is improved.

In addition, in the sixth modification, the fins 250 are provided on a portion of the sidewall which forms one main exhaust slit 236 and the two sub-exhaust slits 238 in the cylindrical portion. The fins 250 protrude from the sidewall toward the outer tube 14. The protrusion length becomes shorter along the axial direction of the cylindrical portion from the opposite side of the main exhaust port and the pair of sub-exhaust ports toward the main exhaust port and the pair of sub-exhaust ports. That is, the distance between the inner tube and the outer tube in the exhaust space becomes shorter in a plan view toward the main exhaust port and the pair of sub-exhaust ports along the vertical direction H.

Here, for example, a case is assumed where the fins 250 are not provided and the distance between the inner tube and the outer tube in the exhaust space is approximately constant in a plan view toward the main exhaust port and the pair of sub-exhaust ports. When the distance between the inner tube and the outer tube is approximately constant, the flow rate of the precursor gas exhausted from a portion close to the main exhaust port in one main exhaust slit 236 is greater than that of the precursor gas exhausted from a portion far from the main exhaust port.

Similarly, the flow rate of the precursor gas exhausted from a portion close to the sub-exhaust port in two sub-exhaust slits 238 is greater than that of the precursor gas exhausted from a portion far from the sub-exhaust port. That is, a difference in the exhaust amount between the top and bottom of one main exhaust slit 236 and two sub-exhaust slits 238 becomes large. As a result, the unevenness in the flow rate of the exhausted precursor gas becomes large between the wafers 200 stacked in multiple stages along the axial direction.

On the other hand, in the sixth modification, the fin 250 suppresses a difference between the flow rate of the precursor gas exhausted from the bottom side close to the main exhaust port and the sub-exhaust port, and the flow rate of the precursor gas exhausted from the top side so as to be small. Therefore, the flow rate of the exhausted precursor gas is equalized between the wafers 200 stacked in multiple stages along the axial direction. As a result, the film inter-surface uniformity between the surfaces of the plurality of wafers 200 is improved. In addition, it is not necessary to process the sidewall of the cylindrical portion so that the opening width of the slit narrows from the side opposite the exhaust port toward the exhaust port along the axial direction.

In addition, in the seventh modification, the main exhaust buffer 232a and the two sub-exhaust buffers 232b are provided to send the precursor gas to the outside. Therefore, the exhaust of the precursor gas to the outside is promoted.

In addition, in this embodiment, the first injection direction F1, which is the closest to the return pipe, among the injection directions of the injection holes 234 of the outward pipe of the return nozzle, and the second injection direction F2, which is the closest to the outward pipe, among the injection directions of the injection holes 234 of the return pipe, intersect each other outside the wafer 200 or inside the supply buffer 222.

Therefore, the precursor gas injected along the first injection direction F1 and the precursor gas injected along the second injection direction F2 collide at a position away from the wafer 200. As a result, the precursor gas with a concentration equalized due to the collision may be supplied to the wafer 200. When the intersection FX is outside the supply buffer 222 and close to the wafer 200, the collision position of the precursor gases is too close to the wafer 200, making it difficult to supply the precursor gas with an equalized concentration to the entire surface of the wafer 200. In addition, when the intersection FX is located outside a distance of 3r from the center C2 of the outward pipe and a distance of 3r from the center C2 of the return pipe, a distance between the collision position of the precursor gases and the wafer 200 becomes short. As a result, it is difficult to supply the precursor gas with the equalized concentration to the entire surface of the wafer 200.

In addition, in this embodiment, the supply buffer 222 is divided into three portions along the circumferential direction of the cylindrical portion by the third partition 18c and the fourth partition 18d. Among the divided portions of the supply buffer 222, the central portion 222b is provided with the return nozzles 340 and 341 provided as the four gas nozzles 340a, 340b, 341a, and 341b, and the gas nozzles 342a and 342c are provided on both sides of the central portion to supply the assist gas and the reaction gas. The assist gas from the gas nozzle 342a and the like makes it easy to adjust the intra-plane or inter-plane uniformity of the concentration of the precursor gas.

In addition, in this embodiment, the counter nozzle 343 which supplies the assist gas is provided as the third injector at a position where the angle between the second virtual line L2 connecting the injection direction of the third injector and the center C1 of the wafer 200 and the virtual plane A is an obtuse angle in a plan view. By mixing the assist gas from the counter nozzle 343 as the third injector with the precursor gas, the uniformity of the concentration of the precursor gas may be further easily adjusted.

When none of the four gas nozzles 340a, 340b, 341a, and 341b as the first injector are used together, the assist gas of 5 slm to 10 slm is required per nozzle such as the gas nozzle 342a. On the other hand, when the first injector is used together, the amount of N₂ used as the assist gas per nozzle of the gas nozzles 342a and the counter nozzle 343 may be reduced to about 1 slm. In addition, the amount of pure N₂ (that is, high-purity N₂) used in the entire substrate processing may be reduced by 10% to 20%.

In this specification, the denotation of a numerical range such as “3 slm to 4 slm” means that the lower limit and the upper limit are included in the range. Therefore, for example, “3 slm to 4 slm” means “3 slm or more and 4 slm or less.” This also holds true for other numerical ranges.

In addition, in this embodiment, the central angle θ of the fan shape formed by the virtual arc connecting both ends in the circumferential direction of the cylindrical portion of the supply buffer 222 and the center C1 of the wafer 200 is less than 30 degrees. When the central angle θ is 30 degrees or more, the circumferential width of the cylindrical portion of the supply buffer 222 becomes wider. As a result, the overall dimensions of the supply buffer 222 become larger. That is, in this embodiment, the circumferential width of the cylindrical portion of the supply buffer 222 may be made narrower than when the central angle θ is 30 degrees or more. Therefore, the overall dimensions of the supply buffer 222 may be reduced.

In addition, in the substrate processing method using the substrate processing apparatus 10 according to this embodiment, the uniformity of the flow of the precursor gas on the surface of the wafer 200 may be improved.

In addition, in a semiconductor device manufacturing method including the substrate processing method according to this embodiment, the uniformity of the flow of the precursor gas on the surface of the wafer 200 may be improved. Thus, a semiconductor device may be manufactured in which the in-plane uniformity and step coverage of the precursor gas adsorbed on the surface of the wafer 200 are improved.

In particular, in the manufacture of semiconductor devices, there are cases where relatively deep pinholes are formed on the surface of the wafer 200, such as in a three-dimensional NAND-type flash memory. The deeper the pinholes, the greater the surface area of the wafer 200. Thus, the amount of precursor gas required for the film-forming process also increases according to the surface area. For this reason, this embodiment, which improves the uniformity of the flow of the precursor gas, may be advantageously applied to the film-forming process in the process of manufacturing a semiconductor device in which relatively deep holes are formed on a surface of the semiconductor device.

### Other Aspects of the Present Disclosure

The present disclosure has been described according to the aspects of the above-disclosed embodiments, but the descriptions and the drawings constituting a portion of the present disclosure are not intended to be taken in a restrictive sense. The present disclosure is not limited to the above embodiments, and various modifications may be made without departing from the gist of the disclosure.

For example, an example in which a film is formed using a batch-type substrate processing apparatus which processes a plurality of substrates at a time have been described in the above-described embodiments. The present disclosure is not limited to the above-described embodiments, and may be suitably applied to, for example, a case where a film is formed using a single-wafer-type substrate processing apparatus which processes one or several substrates at a time.

Further, an example in which a film is formed using a substrate processing apparatus including a hot-wall-type process furnace has been described in the above-described embodiments. However, the present disclosure is not limited to the above-described embodiments, and may be suitably applied to a case where a film is formed using a substrate processing apparatus having a cold-wall-type process furnace.

Even when using these substrate processing apparatuses, each process may be performed with the same processing procedures and process conditions as the above-described embodiments and modifications, and the same effects as in the above-described embodiments and modifications may be obtained.

Further, the present disclosure may be configured by partially combining the configurations included in the above-disclosed embodiments, modifications, and aspects with each other. In the present disclosure configured by such a combination, the process procedures and process conditions to be executed may be configured, for example, similarly to the processing procedures and process conditions described in the aspects related to the present embodiments.

The present disclosure includes various embodiments not described above, and the technical scope of the present disclosure is determined only by the invention-specific matters of the claims that are reasonable from the above description.

The disclosure of Japanese Patent Application No. 2022-017389, filed on Feb. 7, 2022, is incorporated herein by reference in its entirety. In addition, all documents, patent applications, and technical standards described in this specification are incorporated herein by reference to the same extent as if each document, patent application, and technical standard was specifically and individually indicated to be incorporated by reference.

What is claimed is:

1. A substrate processing apparatus comprising:
(a) a process tube including a cylindrical portion which is closed at an upper end and accommodates at least one substrate therein;
(b) a supply buffer provided on a sidewall of the cylindrical portion to protrude outward from the sidewall;
(c) at least one first injector provided inward of the supply buffer to extend along an axial direction of an axis of the cylindrical portion; and
(d) a plurality of exhausters formed in the sidewall of the cylindrical portion to exhaust a precursor gas, the plurality of exhausters including a pair of exhausters open such that both sides of the pair of exhausters sandwich a virtual plane set to pass through a circumferential center of the cylindrical portion and the axis of the cylindrical portion at a boundary between the supply buffer and the cylindrical portion in a plan view.

2. The substrate processing apparatus of claim 1, wherein the plurality of exhausters include one main exhauster formed in the sidewall of the cylindrical portion on an opposite side of the supply buffer with respect to a center of the at least one substrate,
wherein the pair of exhausters are two sub-exhausters arranged at a same height as the one main exhauster and to be spaced apart from the main exhauster, the two sub-exhausters sandwiching the main exhauster,
wherein an angle between a first virtual line connecting a center of each of the two sub-exhausters and the center of the at least one substrate and the virtual plane is an obtuse angle in a plan view, and
wherein a width of each of the two sub-exhausters in a circumferential direction of the cylindrical portion is smaller than a width of the main exhauster.

3. The substrate processing apparatus of claim 1, wherein the at least one first injector includes a plurality of first injectors configured to be arranged along a circumferential direction of the cylindrical portion to be capable of supplying a same precursor gas, and
wherein each of the plurality of first injectors is a return nozzle including an outward pipe and a return pipe through which the precursor gas flows, an upper end of the outward pipe being in communication with an upper end of the return pipe, the outward pipe and the return pipe having injection holes through which the same precursor gas is injected.

4. The substrate processing apparatus of claim 3, wherein the plurality of first injectors includes four first injectors formed by two return nozzles.

5. The substrate processing apparatus of claim 1, wherein the at least one first injector has three or more injection holes arranged along a circumferential direction of the cylindrical portion in a plane parallel to a surface of the at least one substrate.

6. The substrate processing apparatus of claim 1, wherein the at least one first injector and the pair of exhausters are configured in symmetry to the virtual plane.

7. The substrate processing apparatus of claim 1, wherein the at least one substrate includes a plurality of substrates arranged inside the cylindrical portion along the axial direction of the cylindrical portion,
wherein the at least one first injector includes a plurality of first injectors configured to be arranged along a circumferential direction of the cylindrical portion to be capable of supplying the same precursor gas,
wherein the plurality of first injectors include four first injectors, each of the four first injectors including an outward pipe and a return pipe through which the precursor gas flows, an upper end of the outward pipe being in communication with an upper end of the return pipe, the four first injectors being formed by two return nozzles, each of the two return nozzles including the outward pipe and the return pipe, and each of the outward pipe and the return pipe having injection holes through which the same precursor gas is injected,
wherein the two return nozzles are arranged such that the respective return pipes are adjacent to each other and the respective outward pipes are spaced apart from each other,
wherein each of the outward pipes and the return pipes of the two return nozzles has three or more columns of injection holes extending along longitudinal directions of the two return nozzles, and
wherein the three or more columns of injection holes radially inject the precursor gas in a plan view.

8. The substrate processing apparatus of claim 1, wherein the at least one first injector includes a plurality of first injectors configured to be arranged in a circumferential direction of the cylindrical portion to be capable of supplying a same precursor gas,
wherein the substrate processing apparatus further comprises:
a tank connected to each of the plurality of first injectors and configured to store the precursor gas alone without being mixed with a carrier gas, and configured to supply the stored precursor gas to each of the plurality of first injectors in a pulse-like manner substantially simultaneously, and
wherein a total instantaneous maximum flow rate of the precursor gas injected in the pulse-like manner from each of the plurality of first injectors is 5 slm or more.

9. The substrate processing apparatus of claim 5, wherein among the three or more injection holes, a diameter of the injection hole which injects the precursor gas from a center of the substrate toward an outermost side of the substrate is larger than diameters of remaining injection holes.

10. The substrate processing apparatus of claim 5, wherein a space is formed between one of the three or more injection holes, which injects the precursor gas toward an outermost side of the substrate in a plan view, and the substrate, instead of providing a structure between the one injection hole and the substrate, the precursor gas being movable linearly along an injection direction via the space.

11. The substrate processing apparatus of claim 1, wherein the process tube further includes an outer tube configured to form an exhaust space between the cylindrical portion and the outer tube by surrounding the cylindrical portion, the outer tube having an exhaust port through which the exhaust space communicates with an outside of the process tube.

12. The substrate processing apparatus of claim 2, wherein the process tube further includes an outer tube configured to form an exhaust space between the cylindrical portion and the outer tube by surrounding the cylindrical portion, the outer tube having an exhaust port through which the exhaust space communicates with an outside of the process tube, and
wherein a width of an opening of each of the one main exhauster and the pair of sub-exhausters along the circumferential direction of the cylindrical portion is narrowed from a side opposite the exhaust port toward the exhaust port along the axial direction of the cylindrical portion.

13. The substrate processing apparatus of claim 2, wherein the process tube further includes:
an outer tube configured to form an exhaust space between the cylindrical portion and the outer tube by surrounding the cylindrical portion, the outer tube having an exhaust port through which the exhaust space communicates with an outside of the process tube; and
an exhaust flow rate adjuster configured to protrude from the sidewall toward the outer tube in a portion of the sidewall which forms each of the one main exhauster and the pair of sub-exhausters in the cylindrical portion, a length of the exhaust flow rate adjuster protruded from the sidewall being decreased from a side opposite the exhaust port toward the exhaust port along the axial direction of the cylindrical portion.

14. The substrate processing apparatus of claim 2, further comprising: a main exhauster and two sub-exhausters, which are configured to send the precursor gas to the outside.

15. The substrate processing apparatus of claim 3, wherein a first injection direction and a second injection direction intersect with each other outside the substrate, the first injection direction being defined closest to the return pipe, among injection directions of the injection holes of the outward pipe of the return nozzle, and the second injection direction being defined closest to the outward pipe, among injection directions of the injection holes of the return pipe of the return nozzle.

16. The substrate processing apparatus of claim 1, wherein the supply buffer is divided into three portions along a circumferential direction of the cylindrical portion by a partition wall, and
wherein the substrate processing apparatus further comprises:
a return nozzle provided as the at least one first injector in a central portion of the three divided portions of the supply buffer; and
second injectors provided on both sides of the central portion to supply an assist gas.

17. The substrate processing apparatus of claim 7, further comprising:
a third injector configured to supply an assist gas and provided as a counter nozzle at a position where an angle between a second virtual line connecting an injection direction of the third injector and a center of the substrate and the virtual plane is an obtuse angle in a plan view.

18. The substrate processing apparatus of claim 1, wherein a central angle of a fan shape formed by a virtual arc connecting both ends of the supply buffer in a circumferential direction of the cylindrical portion and a center of the substrate is less than 30 degrees.

19. A method of processing a substrate, the method comprising:
(A) accommodating a substrate in a cylindrical portion of a process tube, the cylindrical portion having a closed upper portion;
(B) injecting a precursor gas toward the substrate using a nozzle provided inward of a supply buffer, the supply buffer being provided on a sidewall of the cylindrical portion to protrude outward from the sidewall, and the nozzle being provided to extend along an axial direction of the cylindrical portion; and
(C) exhausting the precursor gas injected in (A) outward of the cylindrical portion using a plurality of exhausters, the plurality of exhausters being formed in the sidewall of the cylindrical portion to exhaust the precursor gas and including a pair of exhausters open such that both sides of the pair of exhausters sandwich a virtual plane set to pass through a circumferential center of the cylindrical portion and an axis of the cylindrical portion at a boundary between the supply buffer and the cylindrical portion in a plan view.

20. A method of manufacturing a semiconductor device, the method comprising:
(α) accommodating a substrate in a cylindrical portion of a process tube, the cylindrical portion having a closed upper portion;
(β) injecting a precursor gas toward the substrate using a nozzle provided inward of a supply buffer, the supply buffer being provided on a sidewall of the cylindrical portion to protrude outward from the sidewall, and the nozzle being provided to extend along an axial direction of the cylindrical portion; and
(γ) exhausting the precursor gas injected in (α) outward of the cylindrical portion using a plurality of exhausters, the plurality of exhausters being formed in the sidewall of the cylindrical portion to exhaust the precursor gas and including a pair of exhausters open such that both sides of the pair of exhausters sandwich a virtual plane set to pass through a circumferential center of the cylindrical portion and an axis of the cylindrical portion at a boundary between the supply buffer and the cylindrical portion in a plan view.
